(19) United States
(12) Patent Application Publication
(10) Pub. No.: US 2023/0082884 A1
(43) Pub. Date: Mar. 16, 2023

(54) SEMICONDUCTOR PACKAGE

(71) Applicant: SAMSUNG ELECTRONICS CO., LTD., Suwon-si (KR)

(72) Inventor: Yeongbeom KO, Cheonan-si (KR)

(73) Assignee: SAMSUNG ELECTRONICS CO., LTD., Suwon-si (KR)

(21) Appl. No.: 17/748,654

(22) Filed: May 19, 2022

(30) Foreign Application Priority Data
Sep. 13, 2021 (KR) 10-2021-0122080

(51) Int. Cl. H01L 25/10; H01L 23/00; H01L 23/48

(52) U.S. Cl. CPC H01L 25/105; H01L 24/16; H01L 24/32; H01L 24/73; H01L 23/481; H01L 2924/1436; H01L 2924/37001; H01L 2924/182; H01L 23/49816

(57) ABSTRACT

A semiconductor package includes a base redistribution layer, a first semiconductor chip on the base redistribution layer, at least two chip stacks stacked on the first semiconductor chip and each including a plurality of second semiconductor chips, a first molding layer covering an upper surface of the first semiconductor chip and surrounding the at least two chip stacks, a third semiconductor chip between the base redistribution layer and the first semiconductor chip, a plurality of connection posts between the base redistribution layer and the first semiconductor chips paced apart from the third semiconductor chip in a horizontal direction, and a second molding layer surrounding the third semiconductor chip and the plurality of connection posts between the base redistribution layer and the first semiconductor chip.

### CROSS-REFERENCE TO RELATED APPLICATION

This application is based on and claims priority under 35 U.S.C. §119 to Korean Patent Application No. 10-2021-0122080, filed on Sep. 13, 2021, in the Korean Intellectual Property Office, the disclosure of which is incorporated by reference herein in its entirety.

### BACKGROUND

The disclosure relates to a semiconductor package, and more particularly, to a semiconductor package including a plurality of semiconductor chips together.

With the rapid development of the electronics industry and the needs of users, electronic devices have been increasingly reduced in size and weight, and accordingly, semiconductor devices, which are core components of electronic devices, are required to include various functions. However, high integration of semiconductor devices has reached a limit. Therefore, semiconductor packages including different types of semiconductor chips have been developed to include various functions.

In addition, as demand for higher capacity of semiconductor devices has increased, and multilayer semiconductor packages in which the same type of semiconductor chips are stacked have been developed.

### SUMMARY

One or more example embodiments provide a semiconductor package including a plurality of semiconductor chips that are compact and ensure operation reliability.

According to an aspect of an example embodiment, a semiconductor package includes: a base redistribution layer; a plurality of package connection members attached to a lower surface of the base redistribution layer; a first semiconductor chip provided on the base redistribution layer; at least two chip stacks stacked on the first semiconductor chip in a vertical direction, each chip stack of the at least two chip stacks including a plurality of second semiconductor chips electrically connected to the first semiconductor chip; a first molding layer covering an upper surface of the first semiconductor chip and surrounding the at least two chip stacks; a third semiconductor chip provided between the base redistribution layer and the first semiconductor chip and overlapping at least a portion of each of the at least two chip stacks in the vertical direction; a plurality of connection posts provided between the base redistribution layer and the first semiconductor chip, the plurality of connection posts being configured to electrically connect the base redistribution layer to the first semiconductor chip and being spaced apart from the third semiconductor chip in a horizontal direction; and a second molding layer surrounding the third semiconductor chip and the plurality of connection posts between the base redistribution layer and the first semiconductor chip.

According to an aspect of an example embodiment, a semiconductor package includes: a base redistribution layer; a plurality of package connection members attached to a lower surface of the base redistribution layer; a connection redistribution layer provided on the base redistribution layer; a main semiconductor chip including a graphics processing unit (GPU), and provided between the base redistribution layer and the connection redistribution layer; a plurality of connection posts provided between the base redistribution layer and the connection redistribution layer to electrically connect the base redistribution layer to the connection redistribution layer, the plurality of connection posts being spaced apart from the main semiconductor chip in a horizontal direction; at least one chip stack electrically connected to the connection redistribution layer, attached to the connection redistribution layer such that at least a portion of the at least one chip stack overlaps the main semiconductor chip in a vertical direction, the at least one chip stack including a plurality of sub-semiconductor chips; a first molding layer covering an upper surface of the connection redistribution layer and surrounding at least some of the plurality of sub-semiconductor chips; and a second molding layer configured to fill a space between the base redistribution layer and the connection redistribution layer and surrounding the plurality of connection posts.

According to an aspect of an example embodiment, a semiconductor package includes: a base redistribution layer; a plurality of package connection members attached to a lower surface of the base redistribution layer; a connection redistribution layer provided on the base redistribution layer; a first semiconductor chip attached on the connection redistribution layer and having including a first active surface; at least two chip stacks, each chip stack of the at least two chip stacks including a plurality of second semiconductor chips having a second active surface facing the first active surface and stacked on the first semiconductor chip in a vertical direction, the at least two chip stacks being apart from each other in a horizontal direction; a first molding layer configured to cover an upper surface of the first semiconductor chip and surrounding the at least two chip stacks; a third semiconductor chip provided between the base redistribution layer and the connection redistribution layer and overlapping at least a portion of each of the at least two chip stacks in the vertical direction; a plurality of connection posts provided apart from each other in the horizontal direction between the base redistribution layer and the connection redistribution layer, the plurality of connection posts being configured to electrically connect the base redistribution layer to the connection redistribution layer; and a second molding layer surrounding the third semiconductor chip and the plurality of connection posts between the base redistribution layer and the connection redistribution layer, wherein corresponding side surfaces of the first molding layer, the first semiconductor chip, the connection redistribution layer, the second molding layer, and the base redistribution layer are aligned with each other in the vertical direction, wherein the first semiconductor chip and the plurality of second semiconductor chips constitute a high bandwidth memory (HBM), and wherein the third semiconductor chip includes a graphics processing unit (GPU) chip.

### BRIEF DESCRIPTION OF THE DRAWINGS

The above and other aspects of certain example embodiments of the disclosure will be more clearly understood from the following detailed description taken in conjunction with the accompanying drawings in which:

FIGS. 1A and 1B are a cross-sectional view and a plan layout view, respectively, of a semiconductor package according to an example embodiment;

FIGS. 2A to 2I are cross-sectional views illustrating a method of manufacturing a semiconductor package, according to example embodiments;

FIG. 3 is a cross-sectional view of a semiconductor package according to example embodiments;

FIG. 4 is a cross-sectional view of a semiconductor package according to example embodiments;

FIGS. 5A to 5D are cross-sectional views illustrating a method of manufacturing a semiconductor package, according to example embodiments;

FIG. 6 is a cross-sectional view of a semiconductor package according to example embodiments;

FIG. 7 is a cross-sectional view of a semiconductor package according to example embodiments;

FIGS. 8A to 8H are cross-sectional views illustrating a method of manufacturing a semiconductor package, according to example embodiments;

FIG. 9 is a cross-sectional view of a semiconductor package according to example embodiments;

FIG. 10 is a cross-sectional view of a semiconductor package according to example embodiments; and

FIG. 11 is a cross-sectional view of a semiconductor package according to example embodiments.

### DETAILED DESCRIPTION

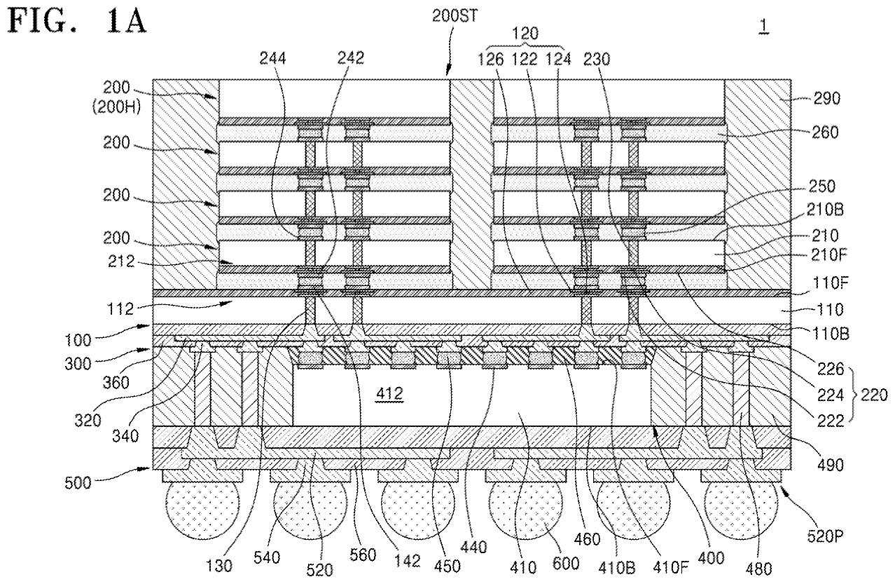

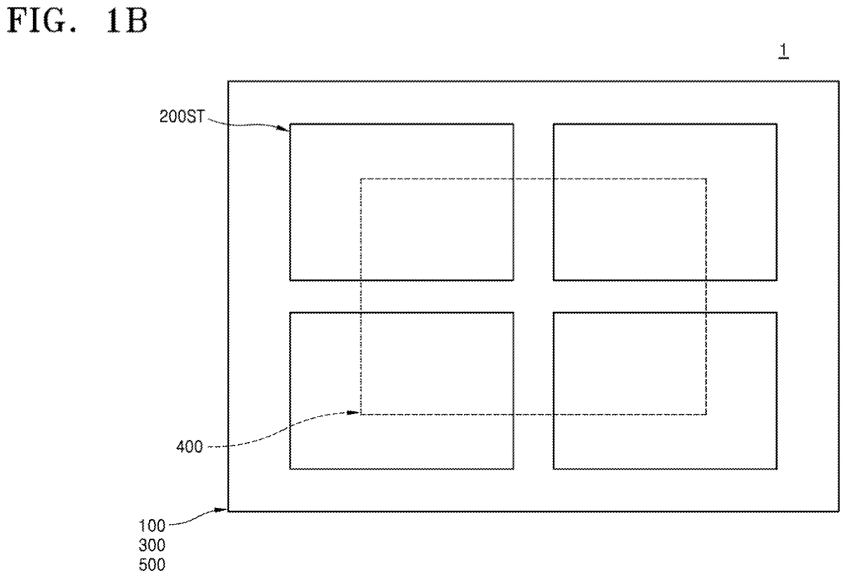

FIGS. 1A and 1B are a cross-sectional view and a plan layout view of a semiconductor package 1 according to example embodiments.

Referring to FIGS. 1A and 1B together, the semiconductor package 1 may include a base redistribution layer 500, a first semiconductor chip 100 disposed on the base redistribution layer 500, a plurality of second semiconductor chips 200 stacked on the first semiconductor chip 100, and a third semiconductor chip 400 disposed between the base redistribution layer 500 and the first semiconductor chip 100. In some embodiments, a connection redistribution layer 300 may be between the third semiconductor chip 400 and the first semiconductor chip 100.

In some embodiments, the semiconductor package 1 may include at least two chip stacks 200ST disposed on the base redistribution layer 500 and apart from each other in a horizontal direction. Each of the at least two chip stacks 200ST may include the second semiconductor chips 200 stacked in a vertical direction. In some embodiments, the semiconductor package 1 may include a multiple of two chip stacks 200ST. For example, the semiconductor package 1 may include two chip stacks 200ST, four chip stacks 200ST, or eight chip stacks 200ST.

The second semiconductor chips 200 may be sequentially stacked on the first semiconductor chip 100 such that a first active surface 110F of the first semiconductor chip 100 faces a second active surface 210F of each of the second semiconductor chips 200. A first wiring layer 120 of the first semiconductor chip 100 may face a second wiring layer 220 of each of the second semiconductor chips 200.

The third semiconductor chip 400 may be referred to as a main semiconductor chip, and the first semiconductor chip 100 and the second semiconductor chips 200 stacked on the first semiconductor chip 100 together may be referred to as a plurality of sub-semiconductor chips.

The first semiconductor chip 100 includes a first substrate 110, the first wiring layer 120, and a plurality of first through-electrodes 130. A plurality of first front chip pads 142 may be disposed on an upper surface of the first semiconductor chip 100.

The second semiconductor chip 200 includes a second substrate 210, a second wiring layer 220, and a plurality of second through-electrodes 230. A plurality of second front chip pads 242 may be disposed on a lower surface of the second semiconductor chip 200, and a plurality of rear connection pads 244 may be disposed on an upper surface of the second semiconductor chip 200.

In some embodiments, a plurality of rear connection pads similar to the rear connection pads 244 of the second semiconductor chip 200 may also be disposed on the lower surface of the first semiconductor chip 100, but the disclosure is not limited thereto. That is, the rear connection pads may not be disposed on the lower surface of the first semiconductor chip 100.

The first substrate 110 and the second substrate 210 may include silicon (Si). Alternatively, the first substrate 110 and the second substrate 210 may include a semiconductor element such as germanium (Ge), or a compound semiconductor such as silicon carbide (SiC), gallium arsenide (GaAs), indium arsenide (InAs), and indium phosphide (InP). The first substrate 110 may have the first active surface 110F and a first non-active surface 110B opposite to the first active surface 110F. The second substrate 210 may have the second active surface 210F and a second non-active surface 210B opposite to the second active surface 210F.

The first substrate 110 and the second substrate 210 may include a plurality of various types of individual devices on the first active surface 110F and the second active surface 210F thereof. The individual devices may include various microelectronic devices, for example, a metal-oxide-semiconductor field effect transistor (MOSFET) such as a complementary metal-oxide-semiconductor transistor (CMOS), image sensors such as a system large scale integration (LSI) or a CMOS imaging sensor (CIS), a micro-electro-mechanical system (MEMS), an active device, a passive device, and the like.

The first semiconductor chip 100 and the second semiconductor chip 200 may include a first semiconductor device 112 and a second semiconductor device 212 configured by the individual devices, respectively. The first semiconductor device 112 may be disposed on the first active surface 110F thereof, and the second semiconductor device 212 may be disposed on the second active surface 210F thereof.

The chip stack 200ST may include a memory chip (e.g., a memory chip stack). The first semiconductor device 112 included in the first semiconductor chip 100 may not include a memory cell, and the second semiconductor device 212 included in the second semiconductor chips 200 may be a memory chip including a memory cell. The first semiconductor device 112 included in the first semiconductor chip 100 may include a serial-parallel conversion circuit, a design for test (DFT), a test logic circuit such as a joint test action group (JTAG), and a memory built-in self-test (MBIST), and a signal interface circuit such as PHY. For example, the first semiconductor chip 100 may be a buffer chip for controlling the second semiconductor chips 200.

In some embodiments, the first semiconductor chip 100 and the second semiconductor chips 200 may constitute a high bandwidth memory (HBM). For example, the first semiconductor chip 100 may be a buffer chip for controlling HBM DRAM, and the second semiconductor chips 200 may be memory cell chips having a cell of the HBM DRAM controlled by the first semiconductor chip 100. The first semiconductor chip 100 may be referred to as a buffer chip, a master chip, or an HBM controller die, and the second semiconductor chip 200 may be referred to as a memory chip, a slave chip, a DRAM die, or a DRAM slice. The first semiconductor chip 100 and the second semiconductor chips 200 stacked on the first semiconductor chip 100 may be collectively referred to as an HBM DRAM device or an HBM DRAM chip.

The first wiring layer 120 may be disposed on the first active surface 110F thereof. The first front chip pads 142 may be disposed on an upper surface of the first wiring layer 120. For example, the first front chip pads 142 may be disposed on an upper surface of the first semiconductor chip 100.

The first wiring layer 120 may include a plurality of first wiring patterns 122, a plurality of first wiring vias 124, and a first interwiring insulating layer 126. The first wiring vias 124 may be connected to upper and/or lower surfaces of the first wiring patterns 122. In some embodiments, the first wiring patterns 122 may be disposed to be apart from each other at different vertical levels, and the first wiring vias 124 may connect the first wiring patterns disposed at different vertical levels to each other. The first wiring patterns 122 and the first wiring vias 124 may be electrically connected to the first through-electrodes 130. The first interwiring insulating layer 126 may surround the first wiring patterns 122 and the first wiring vias 124.

The first through-electrodes 130 may vertically pass through at least a portion of the first substrate 110 to be electrically connected to the first front chip pads 142. In some embodiments, for example, the first through-electrodes 130 may be electrically connected to the first front chip pads 142 through the first wiring patterns 122 and the first wiring vias 124. The first through-electrodes 130 may be electrically connected to the connection redistribution layer 300. For example, the first through-electrodes 130 may electrically connect a plurality of connection redistribution line patterns 320 and a plurality of connection redistribution vias 340 to the first front chip pads 142.

The second wiring layer 220 may be disposed on the second active surface 210F of the second semiconductor chip 200. The second front chip pads 242 may be disposed on a lower surface of the second wiring layer 220. The rear connection pads 244 may be disposed on the second non-active surface 210B.

The second wiring layer 220 may include a plurality of second wiring patterns 222, a plurality of second wiring vias 224, and a second interwiring insulating layer 226. The second wiring vias 224 may be connected to upper and/or lower surfaces of the second wiring patterns 222. In some embodiments, the second wiring patterns 222 may be disposed to be apart from each other at different vertical levels, and the second wiring vias 224 may connect the second wiring patterns disposed at the different levels to each other. The second wiring patterns 222 and the second wiring vias 224 may electrically connect the second through-electrodes 230 to the rear connection pads 244. The second interwiring insulating layer 226 may surround the second wiring patterns 222 and the second wiring vias 224.

The second through-electrodes 230 may vertically pass through at least a portion of the second substrate 210 to electrically connect the second front chip pads 242 to the rear connection pads 244. For example, the second front chip pads 242 may be electrically connected to the rear connection pads 244 through the second through-electrodes 230, the second wiring patterns 222, and the second wiring vias 224.

The first wiring patterns 122, the first wiring vias 124, the second wiring patterns 222, and the second wiring vias 224 may include metal such as copper (Cu) and aluminum (Al)), tungsten (W), titanium (Ti), tantalum (Ta), molybdenum (Mo), cobalt (Co), nickel (Ni), or alloys thereof, or nitrides thereof. The first interwiring insulating layer 126 and the second interwiring insulating layer 226 may include a high density plasma (HDP) oxide, a tetraethyl orthosilicate (TEOS) oxide, tonen silazene (TOSZ), spin on glass (SOG), undoped silica glass (USG) or a low-k dielectric material.

Each of the first through-electrodes 130 and the second through-electrodes 230 may include a conductive plug and a conductive barrier layer surrounding the conductive plug. The conductive plug may include Cu or W. For example, the conductive plug may be formed of Cu, CuSn, CuMg, CuNi, CuZn, CuPd, CuAu, CuRe, CuW, W, or a W alloy, but is not limited thereto. For example, the conductive plug may include Al, Au, Be, Bi, Co, Cu, Hf, In, Mn, Mo, Ni, Pb, Pd, Pt, Rh, Re, Ru, Ta, Te, Ti, W, Zn, and Zr, may include one or more of Zr, and may include one or more multilayer structures. The conductive barrier layer may include at least one material selected from W, WN, WC, Ti, TiN, Ta, TaN, Ru, Co, Mn, WN, Ni, and NiB, and may include a single layer or layers.

In some embodiments, an uppermost second semiconductor chip 200H disposed farthest from the first semiconductor chip 100, among the second semiconductor chips 200, may not include the rear connection pad 244 and the second through-electrode 230. In some embodiments, a thickness of the uppermost second semiconductor chip 200H may be greater than a thickness of the other second semiconductor chips 200.

A plurality of first chip connection members 250 may be respectively attached on the plurality of second front chip pads 242. Each of the first chip connection members 250 may be between the first front chip pad 142 and the second front chip pad 242 that face each other, or between the second front chip pad 242 and the rear connection pad 244 that face each other. In an embodiment, the first chip connection members 250 may be between the first front chip pads 142 and the second front chip pads 242 of the lowermost one of the second semiconductor chips 200 and between the second front chip pads 242 of the other remaining ones of the second semiconductor chips 200 and the rear connection pads 244 of the other second semiconductor chip 200 therebelow to electrically connect the first semiconductor chip to the second semiconductor chips 200, and to electrically connect the second semiconductor chips 200 to each other.

An insulating adhesive layer 260 may be between the first semiconductor chip 100 and the second semiconductor chips 200, that is, between the first semiconductor chip 100 and the lowermost second semiconductor chip 200, and between two second semiconductor chips 200 adjacent to each other, among the second semiconductor chips 200. The insulating adhesive layer 260 may include a non-conductive film (NCF), a non-conductive paste (NCP), an insulating polymer, or an epoxy resin. The insulating adhesive layer 260 may surround the first chip connection member 250 and may fill spaces between the first semiconductor chip 100 and the second semiconductor chips 200.

A horizontal width and a horizontal area of the first semiconductor chip 100 may be greater than a horizontal width and a horizontal area of each of the second semiconductor chips 200. An edge of each of the second semiconductor chips 200 may not be aligned with an edge of the first semiconductor chip 100 in a vertical direction. Edges of each of the second semiconductor chips 200 may be aligned with each other in the vertical direction. For example, the second semiconductor chips 200 may all overlap the first semiconductor chip 100 in the vertical direction.

The semiconductor package 1 may further include a first molding layer 290 surrounding the second semiconductor chips 200 and the insulating adhesive layer 260 on the first semiconductor chip 100. The first molding layer 290 may be formed of, for example, epoxy mold compound (EMC). In some embodiments, the first molding layer 290 may cover side surfaces of the second semiconductor chips 200 and a side surface of the insulating adhesive layer 260 and may not cover an upper surface of the uppermost second semiconductor chip 200H among the second semiconductor chips 200. For example, an upper surface of the first molding layer 290 may be coplanar with an upper surface of the uppermost second semiconductor chip 200H, i.e., the second non-active surface 210B. In some embodiments, the first molding layer 290 may cover the side surfaces of the second semiconductor chips 200, the side surface of the insulating adhesive layer 260, and the upper surface of the uppermost second semiconductor chip 200H together, among the second semiconductor chips 200.

The connection redistribution layer 300 may be disposed on the lower surface of the first semiconductor chip 100, that is, the first non-active surface 110B. The connection redistribution layer 300 may electrically connect the first semiconductor chip 100 and the second semiconductor chips 200 to the third semiconductor chip 400 and the base redistribution layer 500. The connection redistribution layer 300 may include the connection redistribution line patterns 320, the connection redistribution vias 340, and a connection redistribution insulating layer 360.

The connection redistribution line pattern 320 and the connection redistribution via 340 may be formed of metal, for example, copper (Cu), aluminum (Al), tungsten (W), titanium (Ti), tantalum (Ta), or indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), or alloys thereof, but are not limited thereto. In some embodiments, the connection redistribution line pattern 320 and the connection redistribution via 340 may be formed by stacking a metal or an alloy of a metal on a seed layer including titanium, titanium nitride, or titanium tungsten. The connection redistribution insulating layer 360 may be formed from, for example, a photo imageable dielectric (PID) or a photosensitive polyimide (PSPI). In some embodiments, the connection redistribution insulating layer 360 may be stacked in plurality. A thickness of the connection redistribution layer 300 may be about 30 μm to about 70 μm. A thickness of the connection redistribution line pattern 320 may be about 10 μm or less, and a thickness of the connection redistribution insulating layer 360 may be about 10 μm or greater.

The connection redistribution line patterns 320 may be disposed on at least one of an upper surface and a lower surface of the connection redistribution insulating layer 360. Among the connection redistribution line patterns 320, the connection redistribution line pattern 320 disposed on a lower surface of the connection redistribution layer 300 may be referred to as a redistribution connection pad.

The connection redistribution vias 340 may pass through the connection redistribution insulating layer 360 to contact and be connected to some of the connection redistribution line patterns 320, respectively. In some embodiments, at least some of the connection redistribution line patterns 320 may be formed together with some of the connection redistribution vias 340 to form an integral body. For example, the connection redistribution line pattern 320 and the connection redistribution via 340 in contact with an upper surface of the connection redistribution line pattern 320 may form an integral body. In some embodiments, the connection redistribution vias 340 may have a tapered shape extending from a lower side to an upper side thereof to have a narrowing horizontal width. That is, the horizontal width of the connection redistribution vias 340 may widen with increasing distance from the first semiconductor chip 100.

The connection redistribution insulating layer 360 may surround the connection redistribution line patterns 320 and the connection redistribution vias 340.

Some of the connection redistribution line patterns 320 and the connection redistribution vias 340 may be in contact with and electrically connected to the first front chip pads 142. For example, a lower surface of each of the first front chip pads 142 may be in contact with the connection redistribution line pattern 320 or the connection redistribution via 340 disposed on an upper surface of the connection redistribution layer 300. FIG. 1A shows that the connection redistribution via 340 is disposed on the upper surface of the connection redistribution layer 300 so that the lower surface of each of the first front chip pads 142 is in contact with the connection redistribution via 340, but the disclosure is not limited thereto. For example, the connection redistribution line pattern 320 may be disposed on the upper surface of the connection redistribution layer 300, and in this case, the lower surface of each of the first front chip pads 142 may be in contact with and electrically connected to the connection redistribution line pattern 320.

The third semiconductor chip 400 may be attached to a lower surface of the connection redistribution layer 300. The third semiconductor chip 400 may include a third substrate 410 and a plurality of third front chip pads 440. The third substrate 410 may have a third active surface 410F and a third non-active surface 410B opposite to the third active surface 410F. The third semiconductor chip 400 may include a third semiconductor device 412 configured by the individual devices. The third semiconductor device 412 may be disposed on the third active surface 410F thereof. The third front chip pads 440 may be disposed on an upper surface of the third semiconductor chip 400. The third substrate 410 is substantially the same as the first substrate 110 and the second substrate 210, and thus, a detailed description thereof is omitted. The third semiconductor chip 400 may be disposed on the third active surface 410F and may further include a third wiring layer similar to the first wiring layer 120 or the second wiring layer 220.

In this disclosure, the first active surface 110F may be referred to as an active surface of the first semiconductor chip 100 or an active surface of the first substrate 110, the first non-active surface 110B may be referred to as a non-active surface of the first semiconductor chip 100 or a non-active surface of the first substrate 110, the second active surface 210F may be referred to as an active surface of the second semiconductor chip 200 or an active surface of the second substrate 210, the second non-active surface 210B may be referred to as a non-active surface of the second semiconductor chip 200 or a non-active surface of the second substrate 210, the third active surface 410F may be referred to as an active surface of the third semiconductor chip 400 or an active surface of the third substrate 410, and the third non-active surface 410B may be referred to as a non-active surface of the third semiconductor chip 400 or a non-active surface of the third substrate 410. In this disclosure, a front surface and a rear surface refer to surfaces adjacent to the active surface and the non-active surface, and an upper surface and a lower surface refer to surfaces located on upper and lower sides, respectively, in the drawing. The non-active surface of the third substrate 410 may be a lower surface of the third substrate 410 opposite to the third active surface 410F.

The third semiconductor chip 400 may be, for example, a logic semiconductor chip such as a central processing unit (CPU) chip, a graphics processing unit (GPU) chip, or an application processor (AP) chip. In some embodiments, the third semiconductor chip 400 may be a graphics processing device chip.

The third semiconductor chip 400 may be attached to the lower surface of the connection redistribution layer 300 such that the third active surface 410F faces the connection redistribution layer 300. A horizontal width and a horizontal area of the third semiconductor chip 400 may be less than a horizontal width and a horizontal area of the first semiconductor chip 100. In some embodiments, the horizontal width and the horizontal area of the third semiconductor chip 400 may be greater than a horizontal width and a horizontal area of the second semiconductor chip 200. In some embodiments, the third semiconductor chip 400 may be attached to the lower surface of the connection redistribution layer 300 so as to overlap at least a portion of each of the at least two chip stacks 200ST in a vertical direction. The third semiconductor chip 400 may be planarly disposed in the middle of the connection redistribution layer 300.

A plurality of second chip connection members 450 may be attached to the third front chip pads 440. The second chip connection members 450 may be between the third front chip pads 440 and the connection redistribution line patterns 320 disposed on the lower surface of the connection redistribution layer 300. In some embodiments, an underfill layer 460 surrounding the second chip connection members 450 may be between the third semiconductor chip 400 and the connection redistribution layer 300. The underfill layer 460 may be formed of, for example, an epoxy resin formed by a capillary under-fill method.

The base redistribution layer 500 may include a plurality of base redistribution line patterns 520, a plurality of base redistribution vias 540, and a base redistribution insulating layer 560. The base redistribution layer 500 including the base redistribution line patterns 520, the base redistribution vias 540, and the base redistribution insulating layer 560 is substantially similar to the connection redistribution layer 300 including the connection redistribution line patterns 320, the connection redistribution vias 340, and the connection redistribution insulating layer 360, and thus, a description thereof is omitted. A thickness of the base redistribution layer 500 may be equal to or greater than a thickness of the connection redistribution layer 300. The thickness of the base redistribution layer 500 may be about 30 μm to about 90 μm. A thickness of the base redistribution line pattern 520 may be about 10 μm or less, and a thickness of the base redistribution insulating layer 560 may be about 10 μm or greater.

The base redistribution line patterns 520 may be disposed on at least one of an upper surface and a lower surface of the base redistribution insulating layer 560. Among the base redistribution line patterns 520, the base redistribution line pattern 520 disposed on the lower surface of the base redistribution layer 500 may be referred to as an external connection pad 520P.

In some embodiments, at least some of the base redistribution line patterns 520 may be formed together with some of the base redistribution vias 540 to form an integral body. For example, the base redistribution line pattern 520 and the base redistribution via 540 in contact with the upper surface of the base redistribution line pattern 520 may form an integral body. In some embodiments, the base redistribution vias 540 may have a tapered shape extending from a lower side to an upper side thereof to have a narrowing horizontal width. That is, the horizontal width of the base redistribution vias 540 may widen with increasing distance from the third semiconductor chip 400.

The base redistribution insulating layer 560 may surround the base redistribution line patterns 520 and the base redistribution vias 540.

An upper surface of the base redistribution layer 500 may be in contact with the lower surface of the third semiconductor chip 400, that is, the third non-active surface 410B. In some embodiments, the base redistribution line patterns 520 and the base redistribution vias 540 may not be in contact with the third semiconductor chip 400. In some embodiments, some of the base redistribution line patterns 520 and the base redistribution vias 540 may be dummy patterns or dummy vias used for heat transfer, and the dummy patterns and the dummy vias may be in contact with the third non-active surface 410B.

A plurality of connection posts 480 may be between the connection redistribution layer 300 and the base redistribution layer 500 to electrically connect the connection redistribution layer 300 to the base redistribution layer 500. That is, the connection posts 480 may electrically connect the connection redistribution line pattern 320 and the connection redistribution via 340 to the base redistribution line pattern 520 and the base redistribution via 540. The connection posts 480 may be disposed between the connection redistribution layer 300 and the base redistribution layer 500 to be horizontally spaced apart from the third semiconductor chip 400. The connection posts 480 may be disposed along the periphery of the third semiconductor chip 400. Each of the connection posts 480 may include copper (Cu).

Each of the first semiconductor chip 100 and the second semiconductor chip 200 may have a thickness of about 30 μm to about 70 μm. A total thickness of the first semiconductor chip 100 and the chip stack 200ST may be greater than about 200 μm. A thickness of the third semiconductor chip 400 may be equal to or slightly greater than the thickness of each one of the first semiconductor chip 100 and the second semiconductor chip 200. A thickness of the third semiconductor chip 400 may be about 100 μm or less. For example, the thickness of the third semiconductor chip 400 may be about 30 μm to about 80 μm.

The thickness of the third semiconductor chip 400 may be much thinner than a total thickness of the first semiconductor chip 100 and the chip stack 200ST. For example, when n second semiconductor chips 200 are stacked in the chip stack 200ST (n is a multiple of 2), the thickness of the third semiconductor chip 400 may have a value less than 1/n of a total thickness of the first semiconductor chip 100 and the chip stack 200ST.

A thickness of the connection post 480 may be slightly greater than the thickness of the third semiconductor chip 400. For example, the thickness of the connection post 480 may be about 50 μm to about 100 μm, and a second molding layer 490 surrounding the third semiconductor chip 400 and the connection posts 480 may be between the connection redistribution layer 300 and the base redistribution layer 500. The second molding layer 490 may be formed of, for example, EMC. In some embodiments, the second molding layer 490 may cover a side surface of the third semiconductor chip 400, a side surface of the underfill layer 460, and side surfaces of the connection posts 480. The second molding layer 490 may not cover the lower surface of the third semiconductor chip 400, that is, the third non-active surface 410B. The third non-active surface 410B may be in direct contact with the base redistribution layer 500. The third non-active surface 410B of the third semiconductor chip 400, a lower surface of the connection posts 480, and a lower surface of the second molding layer 490 may be located at the same vertical level to form a coplanar surface.

A plurality of package connection members 600 may be respectively attached to the external connection pads 520P. For example, the package connection member 600 may be a solder ball or a bump.

The horizontal width and the horizontal area of the first semiconductor chip 100, the horizontal width and the horizontal area of the connection redistribution layer 300, and the horizontal width and the horizontal area of the base redistribution layer 500 may be the same as the horizontal width and the horizontal area of the semiconductor package 1. For example, the horizontal width and the horizontal area of each of the first semiconductor chip 100, the connection redistribution layer 300, and the base redistribution layer 500 may be substantially the same. The first semiconductor chip 100, the connection redistribution layer 300, and the base redistribution layer 500 may overlap each other in a vertical direction. A horizontal width and a horizontal area of each of the first and second molding layers 290 and 490 may have substantially the same values as the horizontal width and the horizontal areas of each of the first semiconductor chip 100, the connection redistribution layer 300, and the base redistribution layer 500. Respective side surfaces of the first molding layer 290, the first semiconductor chip 100, the connection redistribution layer 300, the second molding layer 490, and the base redistribution layer 500 corresponding to each other may be vertically aligned with each other to be coplanar with each other.

In the semiconductor package 1 according to the disclosure, because the third semiconductor chip 400 is disposed to vertically overlap the first semiconductor chip 100 to which at least two chip stacks 200ST are attached, a size of the semiconductor package 1, that is, the horizontal width and horizontal area, may be minimized, and an electrical connection path between the first semiconductor chip 100, to which at least two chip stacks 200ST are attached, and the third semiconductor chip 400 is shortened, thereby enabling a high-speed operation and improving operation reliability.

In addition, a silicon interposer for electrically connecting the first semiconductor chip 100, to which at least two chip stacks 200ST are attached, to the third semiconductor chip 400 is not necessary, thereby reducing manufacturing costs of the semiconductor package 1.

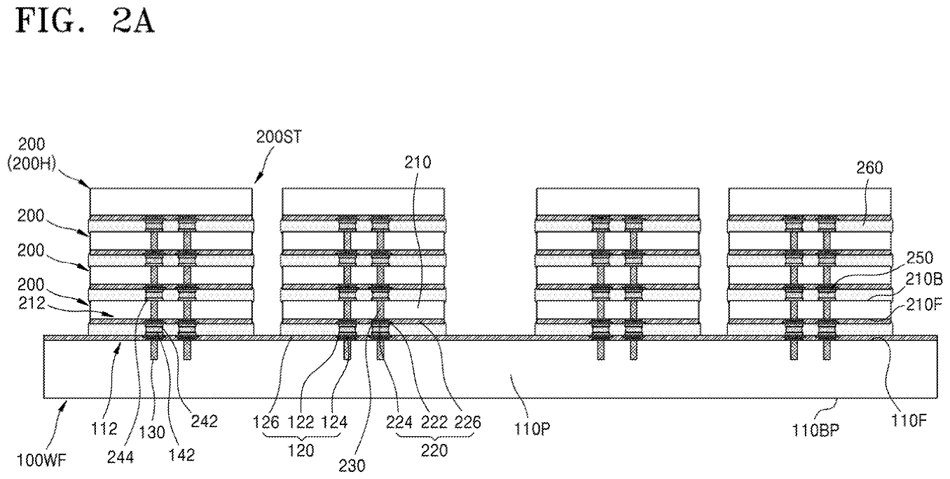

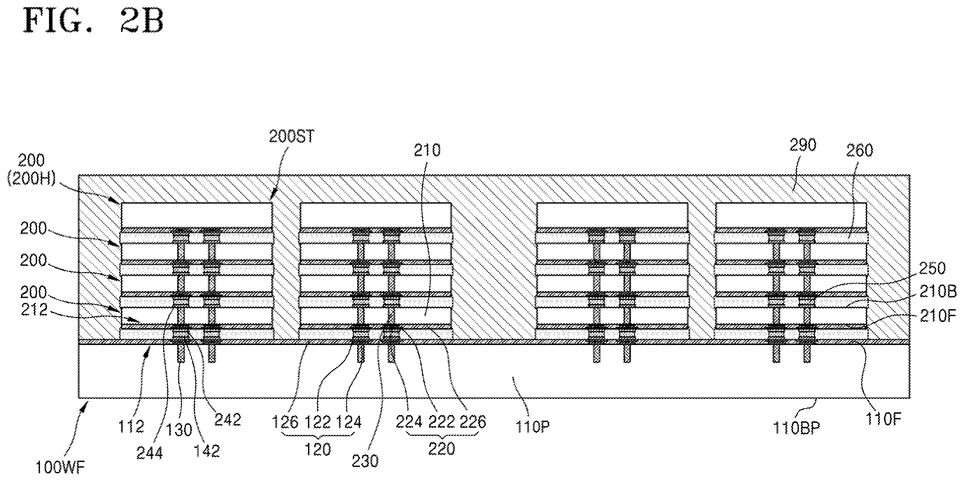

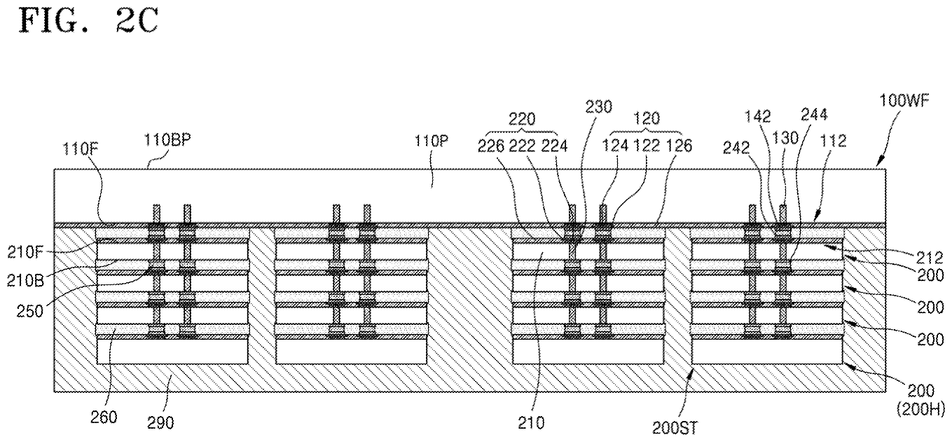

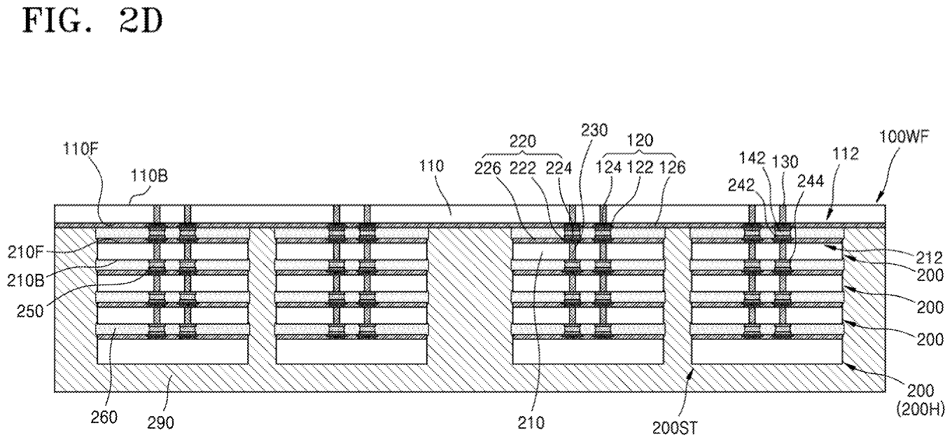

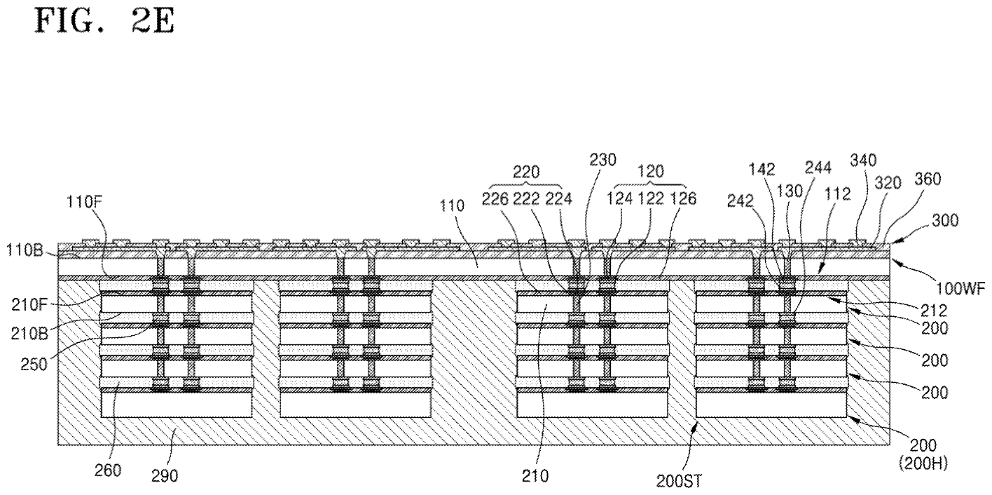

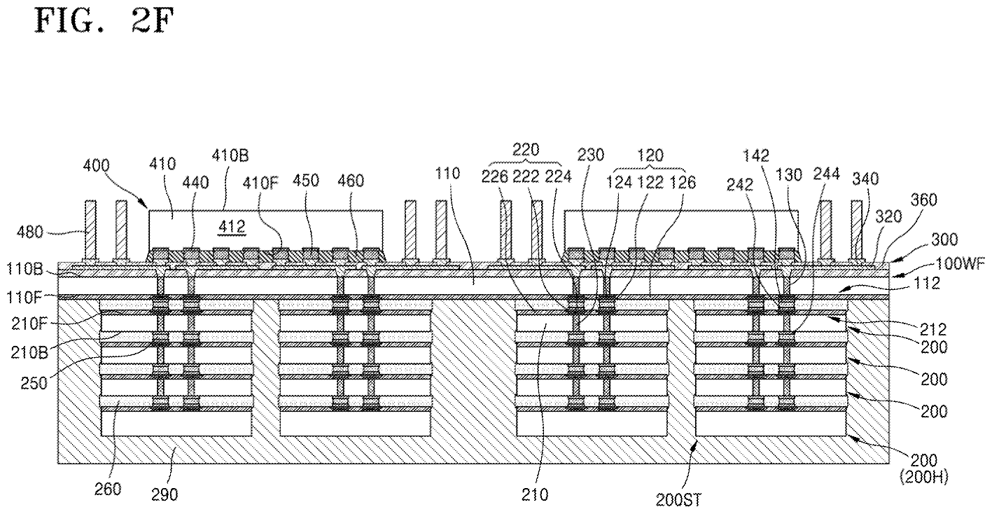

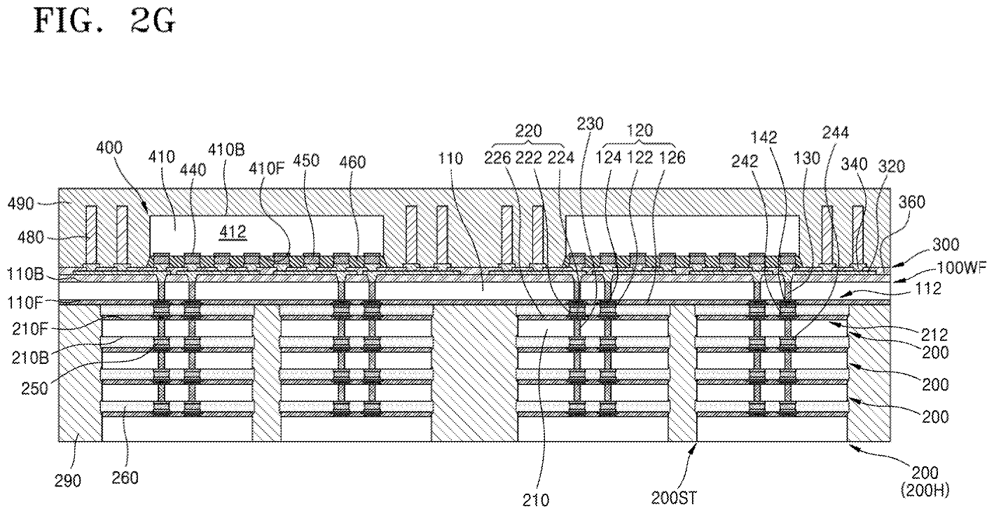

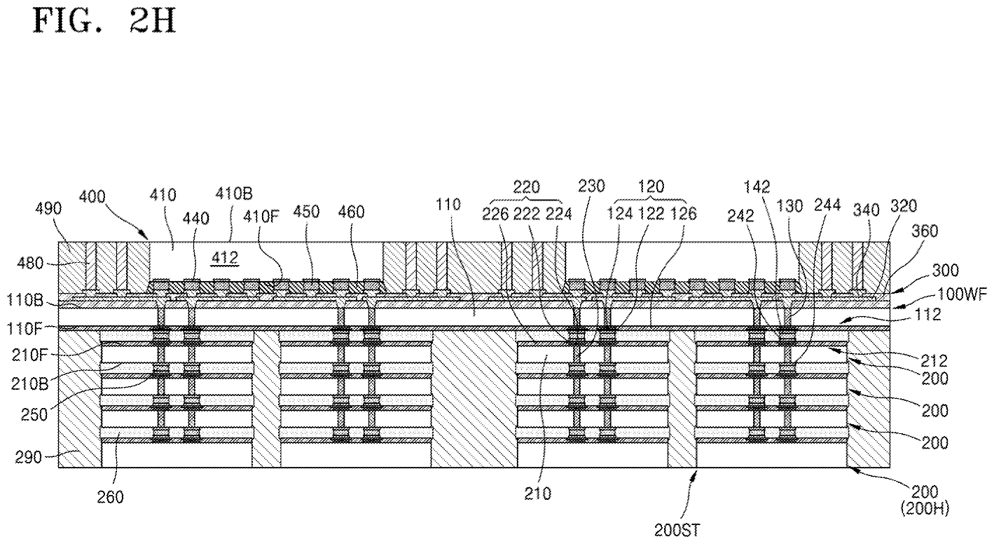

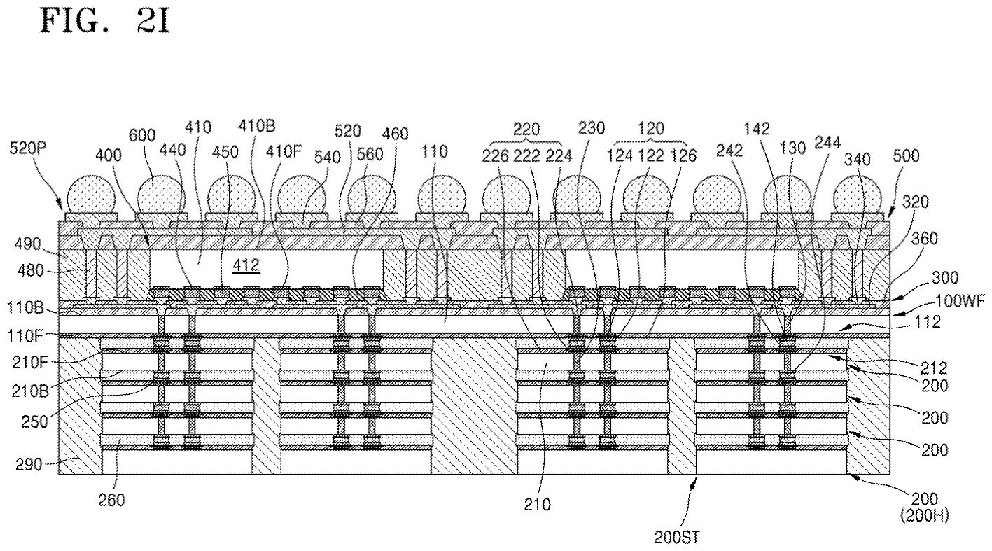

FIGS. 2A to 21 are cross-sectional views illustrating a method of manufacturing a semiconductor package, according to example embodiments, and FIGS. 2A to 21 are cross-sectional views illustrating a method of manufacturing the semiconductor package 1 illustrated in FIGS. 1A and 1B, in which the same reference numerals as those of FIGS. 1A and 1B denote substantially the same members, and the same descriptions as those of FIGS. 1A and 1B are omitted.

Referring to FIG. 2A, a preliminary semiconductor substrate 100WF is prepared. A portion of the preliminary semiconductor substrate 100WF may be the first semiconductor chip 100 shown in FIG. 1A. For example, the preliminary semiconductor substrate 100WF may be a semiconductor wafer on which a plurality of first semiconductor chips 100 shown in FIG. 1A are formed, and may be separated into a plurality of first semiconductor chips 100 in a subsequent process.

The preliminary semiconductor substrate 100WF includes a preliminary substrate 110P, a first wiring layer 120, and a plurality of first through-electrodes 130. The preliminary substrate 110P may have a first active surface 110F and a preliminary non-active surface 110BP opposite to the first active surface 110F. The first wiring layer 120 may be disposed on the first active surface 110F of the preliminary substrate 110P. The first front chip pads 142 may be disposed on an upper surface of the first wiring layer 120. The first through-electrodes 130 may vertically pass through at least a portion of the preliminary substrate 110P to be electrically connected to the first front chip pads 142. In some embodiments, the first through-electrodes 130 may be electrically connected to the first front chip pads 142 through the first wiring patterns 122 and the first wiring vias 124. For example, the first through-electrodes 130 may extend into the preliminary substrate 110P from the first active surface 110F of the preliminary substrate 110P toward the preliminary non-active surface 110BP, but may not completely pass through the preliminary substrate 110P.

A plurality of chip stacks 200ST apart from each other in a horizontal direction are attached to the preliminary semiconductor substrate 100WF. Each of the chip stacks 200ST may include the second semiconductor chips 200 stacked in a vertical direction.

Each second semiconductor chip 200 includes a second substrate 210, a second wiring layer 220, and a plurality of second through-electrodes 230. A plurality of second front chip pads 242 may be formed on a lower surface of the second semiconductor chip 200, and a plurality of rear connection pads 244 may be formed on an upper surface of the second semiconductor chip 200. The second substrate 210 may have a second active surface 210F and a second non-active surface 210B opposite to the second active surface 210F. The second wiring layer 220 may be formed on the second active surface 210F thereof. The second through-electrodes 230 may be formed to vertically pass through at least a portion of the second substrate 210 to expose the second non-active surface 210B. The second front chip pads 242 may be formed on a lower surface of the second wiring layer 220, and the rear connection pads 244 may be formed on the second through-electrodes 230 exposed on the second non-active surface 210B.

For example, the lowermost semiconductor chip 200 to the uppermost second semiconductor chip 200H, among the second semiconductor chips 200 included in each of the chip stacks 200ST, may be sequentially stacked on the preliminary semiconductor substrate 100WF to form chip stacks 200ST including the second semiconductor chips 200 stacked on the preliminary semiconductor substrate 100WF. The chip stack 200ST may be formed by sequentially stacking the second semiconductor chips 200 to which the insulating adhesive layer 260 is attached to the lower surface.

Referring to FIG. 2B, a first molding layer 290 surrounding the chip stacks 200ST is formed on the preliminary semiconductor substrate 100WF. The first molding layer 290 may be formed to cover the side surfaces of the second semiconductor chips 200 and the side surface of the insulating adhesive layer 260 and cover an upper surface of the uppermost second semiconductor chips 200H.

Referring to FIG. 2C, a resultant structure of FIG. 2B is turned over so that the first molding layer 290 faces down and the preliminary semiconductor substrate 100WF faces up, so that the preliminary non-active surface 110BP of the preliminary semiconductor substrate 100WF faces upward.

Referring to FIGS. 2C and 2D together, an upper portion of the preliminary substrate 110P, that is, a portion of the preliminary non-active surface 110BP, is removed to expose the first through-electrodes 130. The upper portion of the preliminary substrate 110P having the first active surface 110F and the preliminary non-active surface 110BP opposite to each other may be removed to form the first substrate 110 having the first active surface 110F and the first non-active surface 110B, which are opposite to each other. One of the ends of the first through-electrodes 130 may be exposed on the first non-active surface 110B of the first substrate 110.

Referring to FIG. 2E, the connection redistribution layer 300 is formed on the first non-active surface 110B of the first substrate 110. The connection redistribution layer 300 may include a plurality of connection redistribution line patterns 320, a plurality of connection redistribution vias 340, and a connection redistribution insulating layer 360.

In some embodiments, at least some of the connection redistribution line patterns 320 may be formed integrally with some of the connection redistribution vias 340. For example, the connection redistribution line pattern 320 and the connection redistribution via 340 in contact with the upper surface of the connection redistribution line pattern 320 may form an integral body. In some embodiments, the connection redistribution vias 340 may be formed to have a tapered shape extending from the lower side to the upper side thereof with a widening horizontal width. That is, the connection redistribution vias 340 may be formed to have the widening horizontal width away from the first semiconductor chip 100.

In some embodiments, the connection redistribution insulating layers 360 may be stacked in plurality. For example, the connection redistribution insulating layer 360, the connection redistribution line pattern 320, and the connection redistribution vias 340 may be repeatedly formed to form the connection redistribution layer 300 in which the connection redistribution insulating layers 360 are stacked.

In some embodiments, after forming the connection redistribution layer 300, an electrical test may be performed on the first semiconductor device 112 included in the preliminary semiconductor substrate 100WF and the second semiconductor device 212 included in the second semiconductor chips 200 through the connection redistribution vias 340 exposed from the upper surface of the connection redistribution layer 300 or the connection redistribution line patterns 320. In some other embodiments, before forming the connection redistribution layer 300, an electrical test may be performed on the first semiconductor device 112 included in the preliminary semiconductor substrate 100W and the second semiconductor device 212 included in the second semiconductor chip 200.

Referring to FIG. 2F, the third semiconductor chip 400 is attached on the connection redistribution layer 300, and the connection posts 480 are formed.

The third semiconductor chip 400 may include a third substrate 410 and the third front chip pads 440. The third substrate 410 may have a third active surface 410F and a third non-active surface 410B opposite to the third active surface 410F. After attaching the second chip connection members 450 to the third front chip pads 440, the third semiconductor chip 400 may be attached to the upper surface of the connection redistribution layer 300 so that the third active surface 410F faces the connection redistribution layer 300. The third semiconductor chip 400 may be attached to the upper surface of connection redistribution layer 300 such that the second chip connection members 450 are connected to some of the connection redistribution line patterns 320 disposed on the upper surface of the connection redistribution layer 300. The underfill layer 460 surrounding the second chip connection members 450 is formed between the third semiconductor chip 400 and the connection redistribution layer 300.

The connection posts 480 may be formed on other connection redistribution line patterns 320 disposed on the upper surface of the connection redistribution layer 300 so as to be apart from the third semiconductor chip 400 in the horizontal direction. In some embodiments, the connection posts 480 may be formed by performing a plating process. For example, the connection posts 480 may be formed by performing electrolytic plating or electroless plating.

In some embodiments, uppermost ends of the connection posts 480 may protrude upward from (e.g., above) the third non-active surface 410B of the third semiconductor chip 400.

Referring to FIG. 2G, the second molding layer 490 surrounding the third semiconductor chip 400 and the connection posts 480 is formed on the connection redistribution layer 300. The second molding layer 490 may be formed to cover the upper surface of the third semiconductor chip 400, that is, the third non-active surface 410B and the upper surface of the connection posts 480.

A lower portion of the first molding layer 290 may be removed to expose the second non-active surface 210B of the uppermost second semiconductor chip 200H.

Referring to FIGS. 2G and 2H together, an upper portion of the second molding layer 490 is removed to expose the third non-active surface 410B and the connection posts 480 of the third semiconductor chip 400. In the process of removing the upper portion of the second molding layer 490, an upper portion of the third substrate 410 of the third semiconductor chip 400 and/or an upper portion of the connection posts 480 are removed, so that the uppermost ends of the connection posts 480, the third non-active surface 410B of the third semiconductor chip 400, and the upper surface of the second molding layer 490 may be positioned at the same vertical level.

Referring to FIG. 21, the base redistribution layer 500 is formed on the second molding layer 490. The base redistribution layer 500 may include the base redistribution line patterns 520, the base redistribution vias 540, and the base redistribution insulating layer 560. The base redistribution line pattern 520 and the base redistribution via 540 may be formed to be electrically connected to the connection posts 480.

In some embodiments, at least some of the base redistribution line patterns 520 may be formed integrally with some of the base redistribution vias 540. For example, the base redistribution line pattern 520 and the base redistribution via 540 in contact with the upper surface of the base redistribution line pattern 520 may form an integral body. In some embodiments, the base redistribution vias 540 may be formed to have a tapered shape extending from the lower side to the upper side thereof with a widening horizontal width. That is, the horizontal width of the base redistribution vias 540 may increase away from the third semiconductor chip 400. Among the base redistribution line patterns 520, the base redistribution line pattern 520 disposed on the upper surface of the base redistribution layer 500 may be referred to as an external connection pad 520P.

In some embodiments, the base redistribution insulating layers 560 may be stacked in plurality. For example, the base redistribution insulating layers 560, the base redistribution line pattern 520 and the base redistribution vias 540 may be repeatedly formed to form the base redistribution layer 500 in which the base redistribution insulating layers 560 are stacked.

A lower surface of the base redistribution layer 500 may be formed to be in contact with the upper surface of the third semiconductor chip 400, that is, the third non-active surface 410B. In some embodiments, the base redistribution line patterns 520 and the base redistribution vias 540 may be formed not to be in contact with the third semiconductor chip 400. For example, the third non-active surface 410B may be entirely covered by the base redistribution insulating layer 560.

The package connection members 600 may be respectively attached to the external connection pads 520P.

Thereafter, the base redistribution layer 500, the second molding layer 490, the preliminary semiconductor substrate 100WF, and the first molding layer 290 may be cut to form the semiconductor package 1 shown in FIGS. 1A and 1B.

Referring to FIGS. 1A to 2I, in the method of manufacturing the semiconductor package 1 according to the disclosure, an electrical test may be performed on the first semiconductor device 112 and the second semiconductor device 212 before the third semiconductor chip 400 is attached. Accordingly, defects that may occur in the process of forming the chip stack 200ST may be checked in advance, thereby improving the yield of the semiconductor package 1 and reducing the manufacturing cost.

In addition, in the case of disposing the first semiconductor chip 100 to which the at least two chip stacks 200ST are attached and the third semiconductor chip 400 in the horizontal direction, the thickness of the third semiconductor chip 400 may be formed to be similar to the overall thickness of the first semiconductor chip and the chip stack 200ST; however, because the first semiconductor chip 100 to which at least two chip stacks 200ST are attached and the third semiconductor are arranged in the vertical direction, the thickness of the third semiconductor chip 400 may be reduced, and thus, a total volume of the semiconductor package 1 may be reduced.

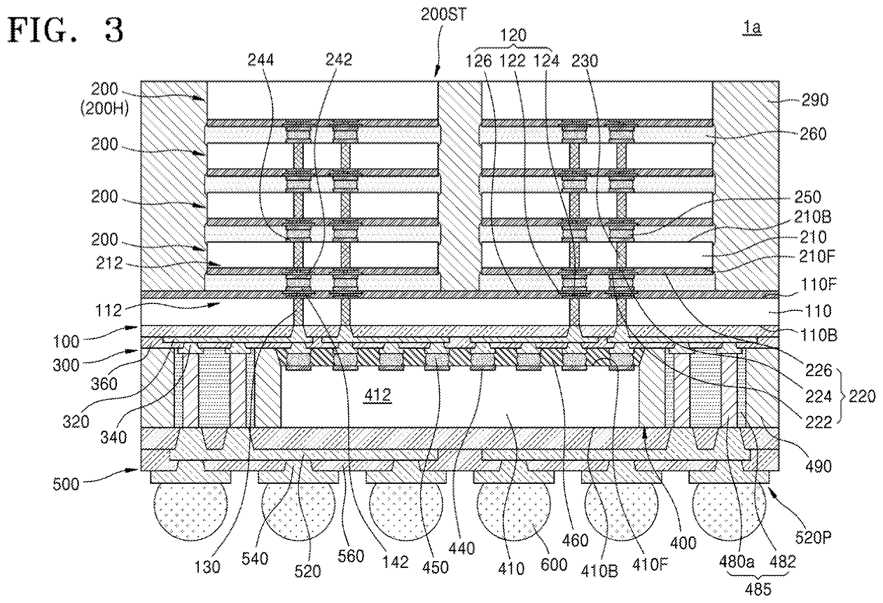

FIG. 3 is a cross-sectional view of a semiconductor package la according to example embodiments. In FIG. 3, the same reference numerals as those of FIGS. 1A and 1B denote substantially the same members, and the same description as those of FIGS. 1A and 1B may be omitted.

Referring to FIG. 3, the semiconductor package la includes a base redistribution layer 500, a first semiconductor chip 100 disposed on the base redistribution layer 500, at least two chip stacks 200ST each including the second semiconductor chips 200 stacked on the first semiconductor chip 100, a third semiconductor chip 400 disposed between the base redistribution layer 500 and the first semiconductor chip 100, a first molding layer 290 surrounding the at least two chip stacks 200ST on the first semiconductor chip 100, and a second molding layer 490 surrounding the third semiconductor chip 400 on the base redistribution layer 500. In some embodiments, the semiconductor package 1a may further include a connection redistribution layer 300 between the first semiconductor chip 100 and the second molding layer 490.

The semiconductor package 1a may include a plurality of connection bars 485 interposed between the connection redistribution layer 300 and the base redistribution layer 500 to electrically connect the connection redistribution layer 300 to the base redistribution layer 500. The connection bar 485 may include a plurality of connection posts 480a and a cover insulating layer 482 surrounding the connection posts 480a. Each of the connection posts 480a may include copper (Cu). The cover insulating layer 482 may include a resin.

In some embodiments, the connection posts 480 shown in FIG. 1A may be formed by performing a plating process as described above with reference to FIG. 2F, but the connection post 480a shown in FIG. 3 may be separately formed first as a connection bar 485 together with the cover insulating layer 482 surrounding the connection posts 480, and then the combination of the connection post 480a and the cover insulating layer 482 may be attached to the connection redistribution layer 300 so as to be interposed between the connection redistribution layer 300 and the base redistribution layer 500.

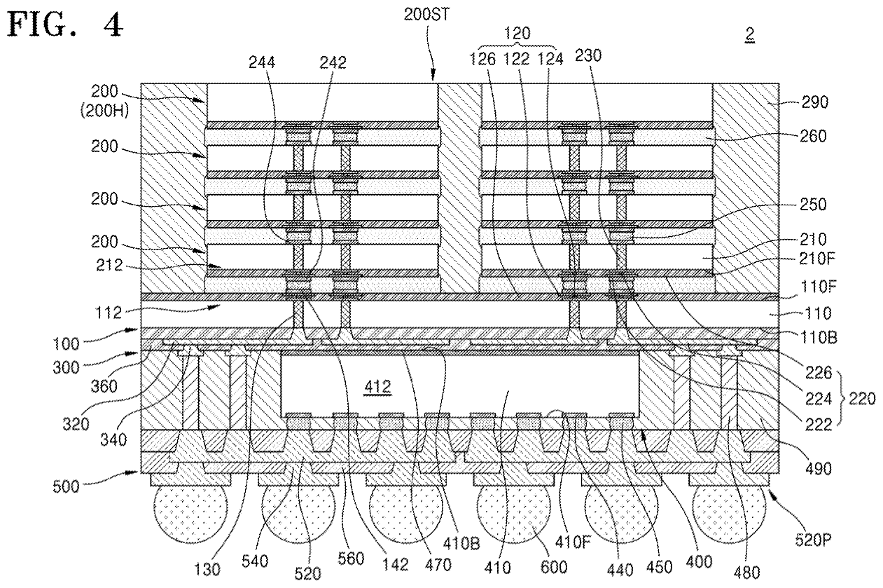

FIG. 4 is a cross-sectional view of a semiconductor package 2 according to example embodiments. In FIG. 4, the same reference numerals as those of FIGS. 1A and 1B denote substantially the same members, and the same description as those of FIGS. 1A and 1B may be omitted.

Referring to FIG. 4, the semiconductor package 2 may include a base redistribution layer 500, a first semiconductor chip 100 disposed on the base redistribution layer 500, at least two chip stacks 200ST each including the second semiconductor chips 200 stacked on the first semiconductor chip 100, the third semiconductor chip 400 disposed between the base redistribution layer 500 and the first semiconductor chip 100,the first molding layer 290 surrounding at least two chip stacks 200ST on the first semiconductor chip 100, the second molding layer 490 interposed between the first semiconductor chip and the base redistribution layer 500 to surround the third semiconductor chip 400, and the connection posts 480 passing through the second molding layer to be interposed between the first semiconductor chip 100 and the base redistribution layer 500. In some embodiments, the semiconductor package 2 may further include a connection redistribution layer 300 interposed between the first semiconductor chip 100 and the second molding layer 490.

The third semiconductor chip 400 may be disposed such that the third active surface 410F faces the base redistribution layer 500. The second chip connection members 450 may be attached to the third front chip pads 440. The second chip connection members 450 may be between the third front chip pads 440 and the base redistribution vias 540 or the base redistribution line patterns 520 disposed on the lower surface of the base redistribution layer 500 to electrically connect the third semiconductor chip 400 to the base redistribution layer 500. The second molding layer 490 may fill a space between the third semiconductor chip 400 and the base redistribution layer 500 and surround the second chip connection members 450. The semiconductor package 2 may not include the underfill layer 460 shown in FIG. 1A.

The lower surfaces of the second chip connection members 450, the lower surfaces of the connection posts 480, and the lower surface of the second molding layer 490 may be located at the same vertical level to form a coplanar surface.

A die adhesive film 470 may be attached to the third non-active surface 410B of the third semiconductor chip 400. In some embodiments, the die adhesive film 470 may fill a space between the third non-active surface 410B of the third semiconductor chip 400 and the lower surface of the connection redistribution layer 300.

In some other embodiments, when the semiconductor package 2 does not include the connection redistribution layer 300, the die adhesive film 470 may fill a space between the third non-active surface 410B of the third semiconductor chip 400 and the first non-active surface 110B of the first semiconductor chip 100. When the semiconductor package 2 does not include the connection redistribution layer 300, the first through-electrodes 130 may be positioned inside the first substrate to be aligned with the connection posts 480 in the vertical direction so as to be directly connected to the connection posts 480.

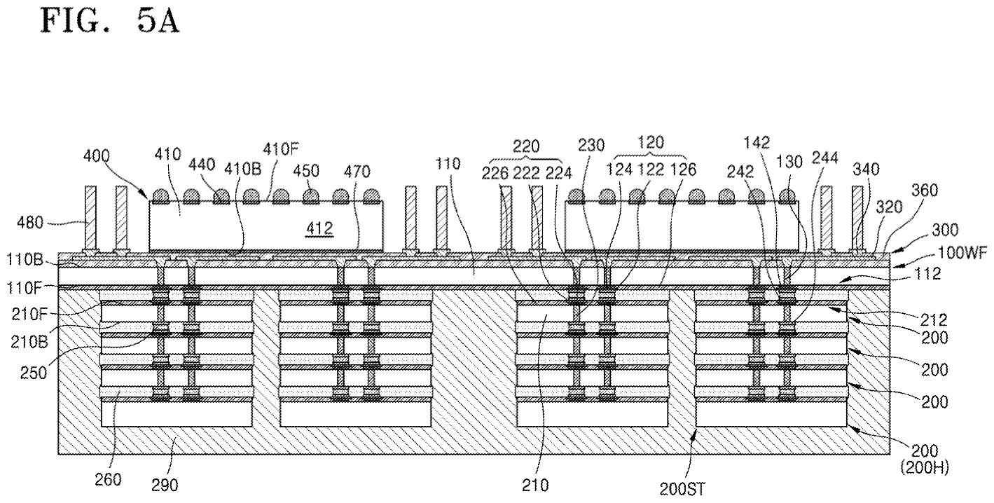

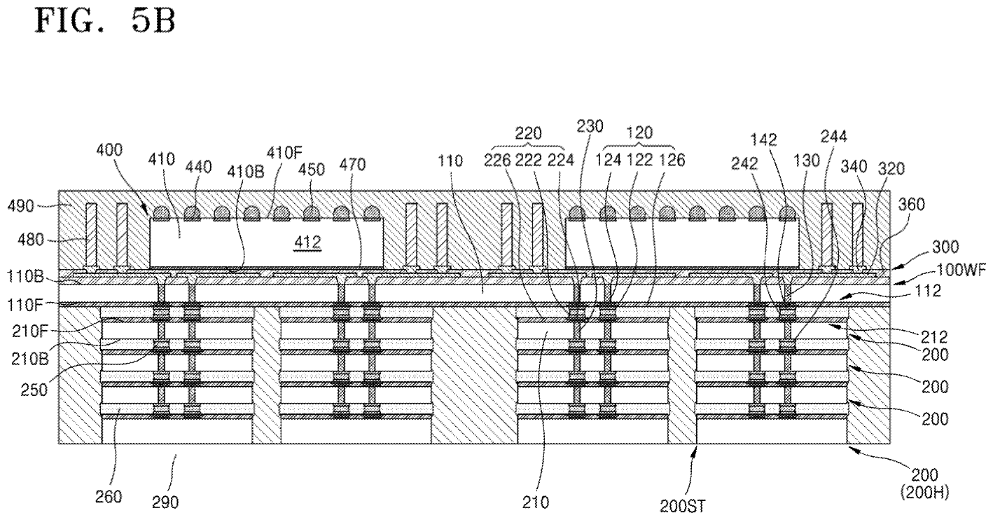

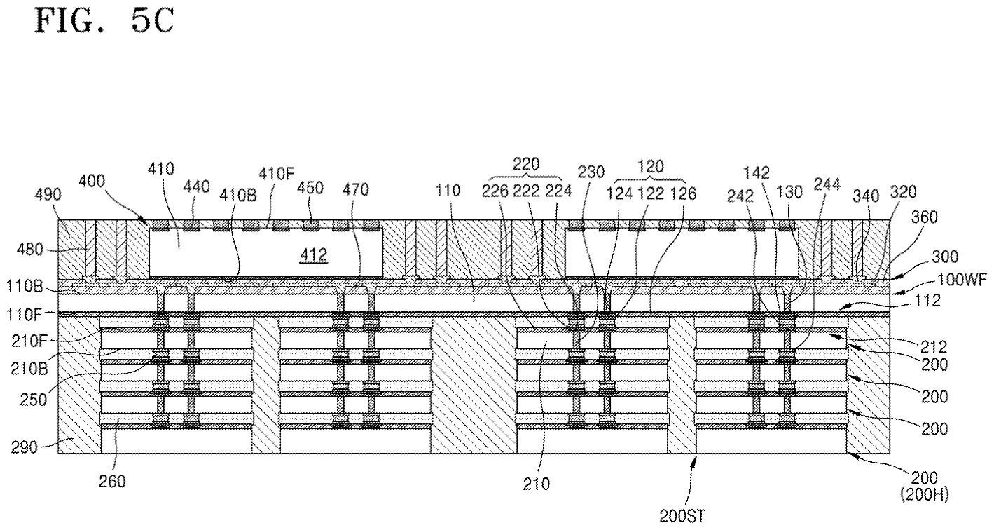

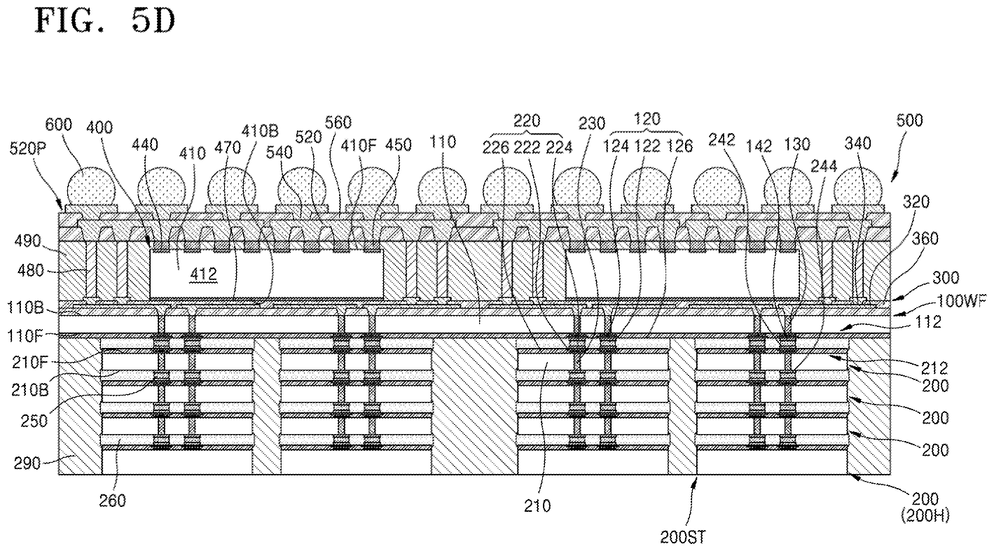

FIGS. 5A to 5D are cross-sectional views illustrating a method of manufacturing a semiconductor package, according to embodiments. FIGS. 5A to 5D are cross-sectional views illustrating a method of manufacturing the semiconductor package 2 shown in

FIG. 4, in which the same reference numerals as those of FIG. 4 denote substantially the same members, and the same description as those of the previous drawings may be omitted.

Referring to FIG. 5A, in a resultant structure of FIG. 2E, the third semiconductor chip 400 is attached on the connection redistribution layer 300 and the connection posts 480 are formed. After attaching the second chip connection members 450 to the third front chip pads 440, the third semiconductor chip 400 may be attached to the upper surface of the connection redistribution layer 300 so that the third non-active surface 410B faces the connection redistribution layer 300. The third semiconductor chip 400 may be attached to the upper surface of the connection redistribution layer 300 after the die adhesive film 470 is attached to the non-active surface 410B.

When the semiconductor package 2 shown in FIG. 4 does not include the connection redistribution layer 300, the third semiconductor chip 400 may be attached to the upper surface of the first semiconductor chip 100 such that the third non-active surface 410B faces the first non-active surface 110B after the second chip connection members 450 are attached to the third front chip pads 440. The third semiconductor chip 400 may be attached to the upper surface of the first semiconductor chip 100 after the die adhesive film 470 is attached to the non-active surface 410B.

Referring to FIG. 5B, the second molding layer 490 surrounding the third semiconductor chip 400 and the connection posts 480 is formed thereon. The second molding layer 490 covers the upper surface of the third semiconductor chip 400, that is, the third active surface 410F and the upper surface of the connection posts 480, and surrounds the second chip connection members 450.

A lower portion of the first molding layer 290 may be removed to expose the second non-active surface 210B of the uppermost second semiconductor chip 200H.

Referring to FIGS. 5B and 5C together, an upper portion of the second molding layer 490 is removed to expose the second chip connection members 450 and the connection posts 480. In the process of removing the upper portion of the second molding layer 490, upper portions of the second chip connection members 450 and/or upper portions of the connection posts 480 may be removed, so that the uppermost end of the second chip connection member 450, the uppermost end of the connection posts 480, and the upper surface of the second molding layer 490 may be positioned at the same vertical level.

Referring to FIG. 5D, the base redistribution layer 500 is formed on the second molding layer 490, and the package connection members 600 are attached to the external connection pads 520P. The base redistribution line pattern 520 and the base redistribution via 540 may be formed to be electrically connected to the second chip connection members 450 and the connection posts 480.

Thereafter, the base redistribution layer 500, the second molding layer 490, the preliminary semiconductor substrate 100WF, and the first molding layer 290 may be cut to form a plurality of semiconductor packages 2 shown in FIG. 4.

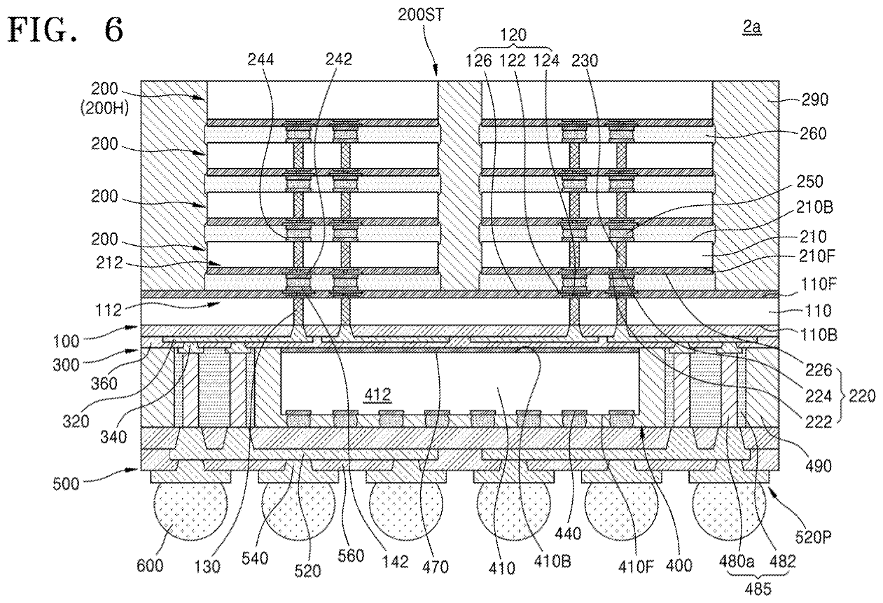

FIG. 6 is a cross-sectional view of a semiconductor package 2a according to example embodiments. In FIG. 6, the same reference numerals as those of FIG. 4 denote substantially the same members, and the same description as those of FIG. 4 may be omitted.

Referring to FIG. 6, the semiconductor package 2a may include a base redistribution layer 500, a first semiconductor chip 100 disposed on the base redistribution layer 500, at least two chip stacks 200ST each including the second semiconductor chips 200 stacked on the first semiconductor chip 100, a third semiconductor chip 400 disposed between the base redistribution layer 500 and the first semiconductor chip 100, a first molding layer 290 surrounding the at least two chip stacks 200ST on the first semiconductor chip, and a second molding layer 490 interposed between the first semiconductor chip 100 and the base redistribution layer 500 and surrounding the third semiconductor chip 400. In some embodiments, the semiconductor package 2a may further include a connection redistribution layer 300 interposed between the first semiconductor chip 100 and the second molding layer 490.

The semiconductor package 2a may include the connection bars 485 interposed between the connection redistribution layer 300 and the base redistribution layer 500 or between the first semiconductor chip 100 and the base redistribution layer 500 and electrically connecting the connection redistribution layer 300 to the base redistribution layer 500 or the first semiconductor chip 100 to the base redistribution layer 500. The connection bar 485 may include the connection posts 480a and the cover insulating layer 482 surrounding the connection posts 480a.

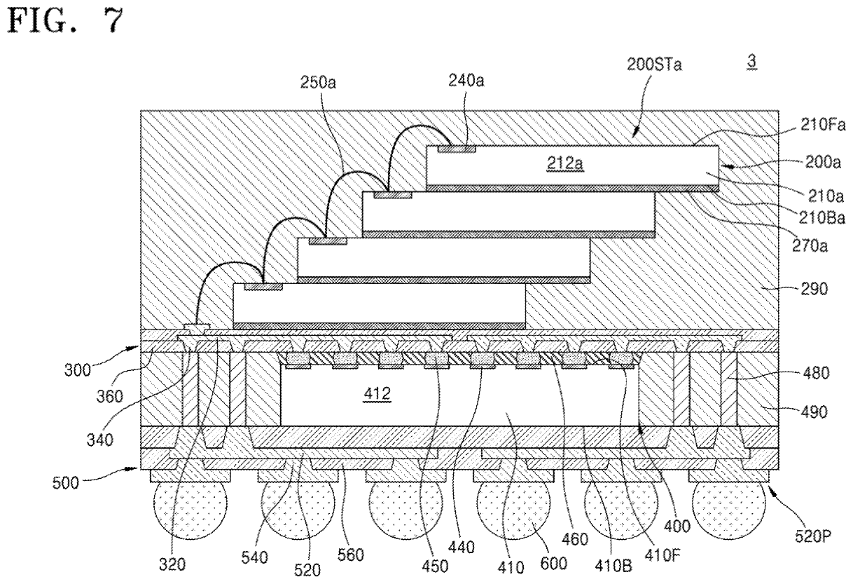

FIG. 7 is a cross-sectional view of a semiconductor package 3 according to example embodiments.

In FIG. 7, the same reference numerals as those of FIGS. 1A and 1B denote substantially the same members, and the same description as those of FIGS. 1A and 1B may be omitted.

Referring to FIG. 7, the semiconductor package 3 may include a main semiconductor chip 400 disposed on a base redistribution layer 500, a connection redistribution layer 300 disposed on the main semiconductor chip 400, at least one chip stack 200STa disposed on the connection redistribution layer 300, a first molding layer 290 surrounding a plurality of sub-semiconductor chips 200a on the connection redistribution layer 300, a second molding layer 490 interposed between the connection redistribution layer 300 and the base redistribution layer 500 and surrounding the main semiconductor chip 400, and connection posts 480 passing through the second molding layer 490 and interposed between the connection redistribution layer 300 and the base redistribution layer 500.

The base redistribution layer 500, the main semiconductor chip 400, and the connection redistribution layer 300 are substantially similar to the base redistribution layer 500, the third semiconductor chip 400, and the connection redistribution layer 300 described above with reference to FIG. 1A, and thus, a redundant description thereof may be omitted. The main semiconductor chip 400 may be, for example, a CPU chip, a GPU chip, or an AP chip. In some embodiments, the main semiconductor chip 400 may be a GPU chip.

The main semiconductor chip 400 may include the third substrate 410 and the third front chip pads 440. The third substrate 410 may have the third active surface 410F and the third non-active surface 410B opposite to the third active surface 410F. The third front chip pads 440 may be disposed on the upper surface of the third semiconductor chip 400.

The main semiconductor chip 400 may be attached to the lower surface of the connection redistribution layer 300 such that the third active surface 410F faces the connection redistribution layer 300. The second chip connection members 450 may be attached to the third front chip pads 440. The second chip connection members 450 may be between the third front chip pads 440 and the connection redistribution line patterns 320 disposed on the lower surface of the connection redistribution layer 300. In some embodiments, the underfill layer 460 surrounding the second chip connection members 450 may be between the main semiconductor chip 400 and the connection redistribution layer 300. The lower surface of the main semiconductor chip 400, that is, the third non-active surface 410B, may be in contact with the upper surface of the base redistribution layer 500.

At least one chip stack 200STa may include a plurality of sub-semiconductor chips 200a that are stacked. The chip stack 200STa may include a memory chip. The sub-semiconductor chip 200a may be a memory chip. In some embodiments, the sub-semiconductor chip 200a may be a dynamic random access memory (DRAM) chip. The sub-semiconductor chips 200a included in at least one chip stack 200STa may be shifted in a horizontal direction and stacked in a step shape in a vertical direction. The sub-semiconductor chip 200a may include a fourth substrate 210a on which a fourth semiconductor device 212a is formed, and a plurality of fourth front chip pads 240a may be disposed on an upper surface 210Fa of the sub-semiconductor chip 200a. A lower surface of the sub-semiconductor chip 200a may be a fourth non-active surface 210Ba. Each of the sub-semiconductor chips 200a may be sequentially stacked on the connection redistribution layer 300 after a sub-die adhesive film 270a is attached to the fourth non-active surface 210Ba, which is a lower surface.

Each of the fourth substrate 210a, the fourth semiconductor device 212a, and the fourth front chip pad 240a are substantially similar to the second substrate 210, the second semiconductor device 212, and the second front chip pad 240, and thus a redundant description thereof may be omitted. The sub-semiconductor chip 200a may further include a wiring layer similar to the second wiring layer 220 described above with reference to FIG. 1A.

In some embodiments, the main semiconductor chip 400 may be attached to the lower surface of the connection redistribution layer 300 so as to overlap at least a portion of each of the at least one chip stack 200STa in a vertical direction. The third semiconductor chip 400 may be planarly disposed in the middle of the connection redistribution layer 300.

A plurality of fourth chip connection members 250a may be attached to the fourth front chip pads 240a. For example, each of the fourth chip connection members 250a may be a bonding wire. The fourth chip connection members 250a may electrically connect the fourth front chip pads 240a included in the sub-semiconductor chips 200a to the connection redistribution line pattern 320.

The first molding layer 290 may further include the first molding layer 290 surrounding the chip stack 200STa and the fourth chip connection members 250a on the connection redistribution layer 300. The first molding layer 290 may cover the upper surface of the chip stack 200STa, that is, the upper surface of the uppermost sub-semiconductor chip 200a among the sub-semiconductor chips 200a.

The second molding layer 490 may be between the connection redistribution layer 300 and the base redistribution layer 500 to surround the main semiconductor chip 400 and the connection posts 480. The third non-active surface 410B of the main semiconductor chip 400, the lower surface of the connection posts 480, and the lower surface of the second molding layer 490 may be positioned at the same vertical level to be coplanar with each other.

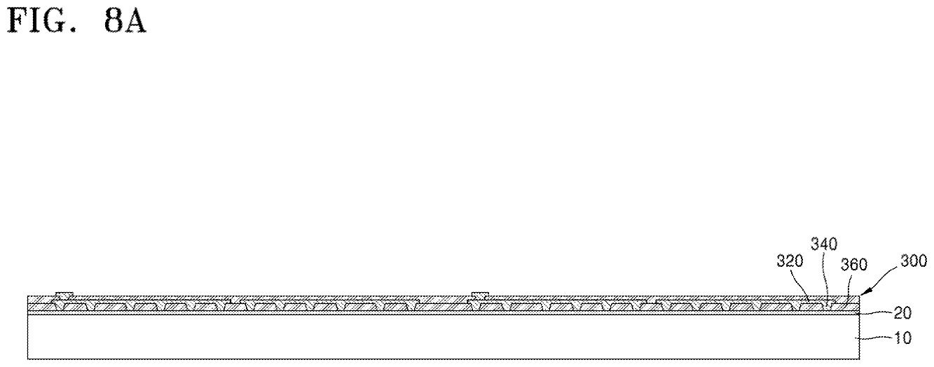

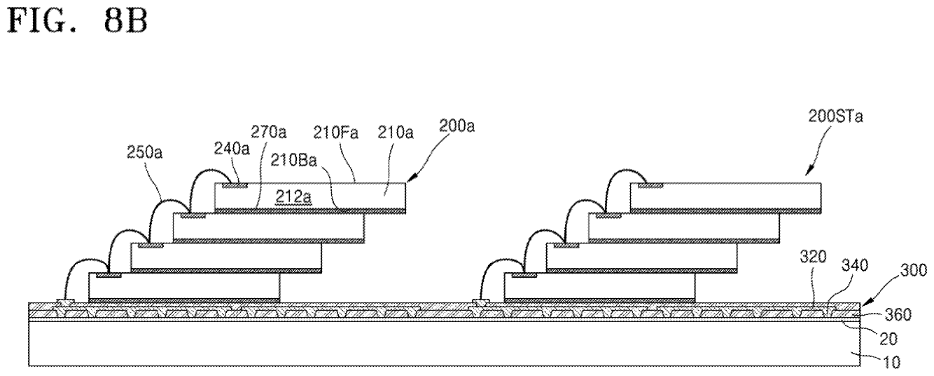

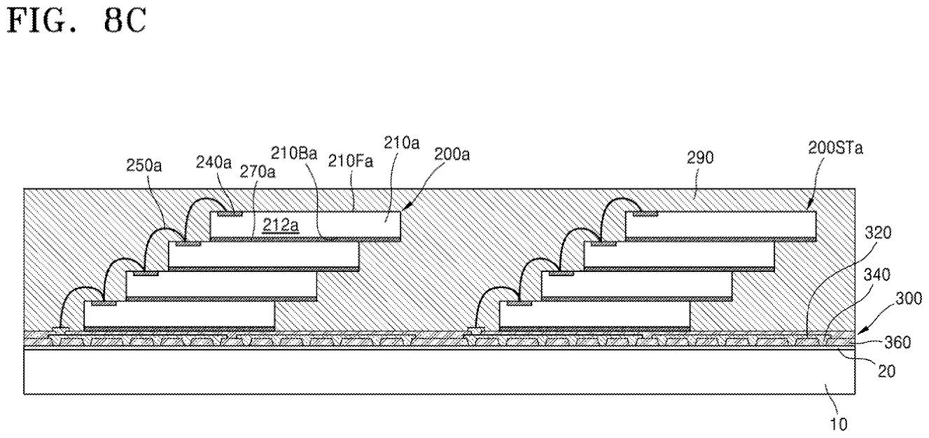

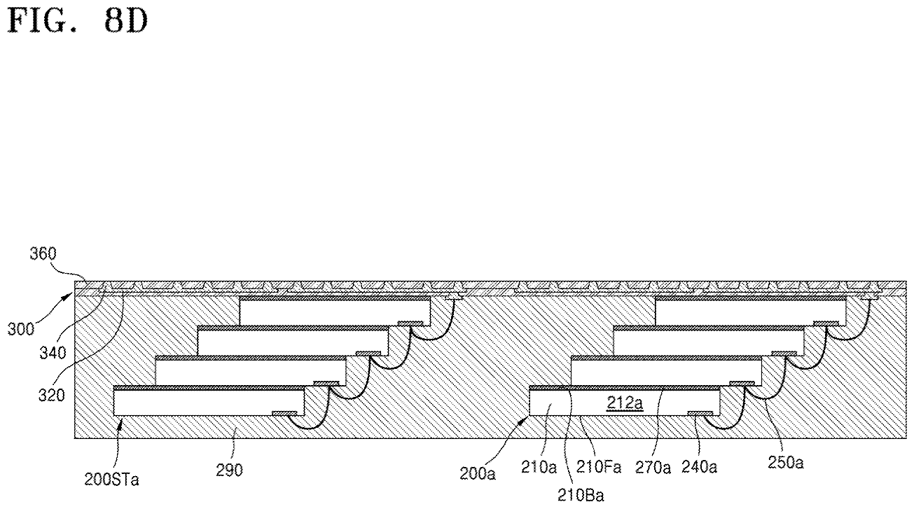

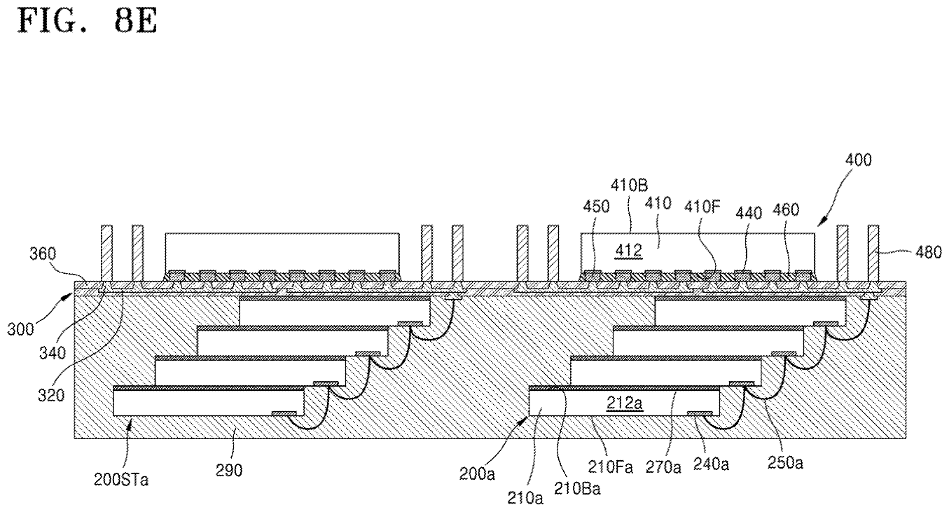

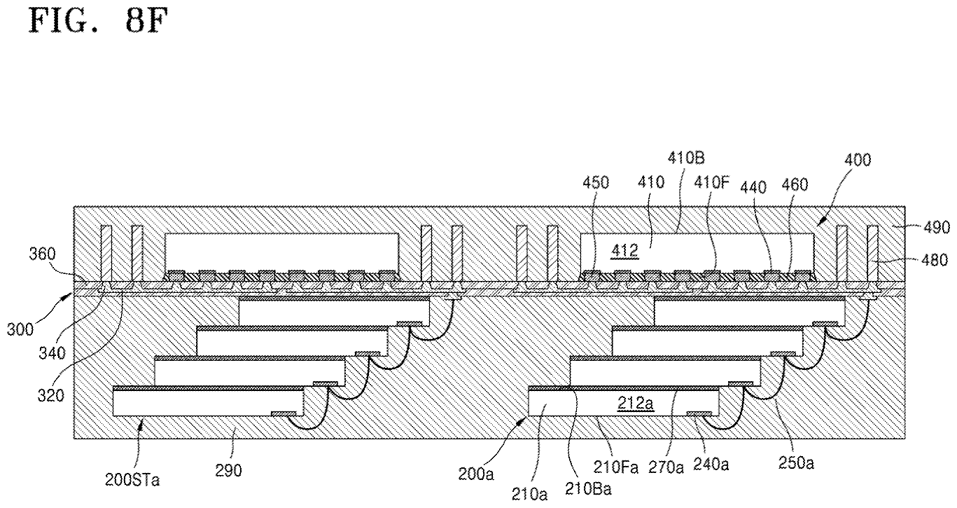

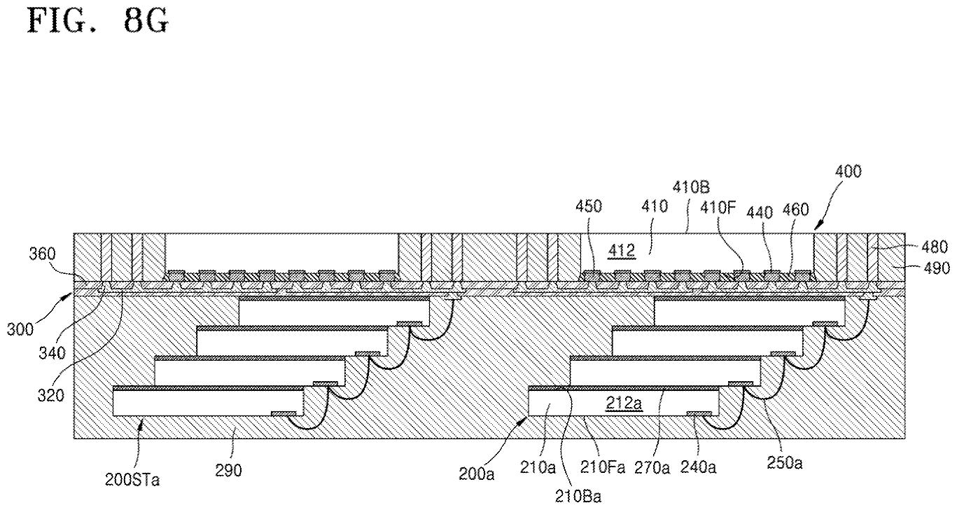

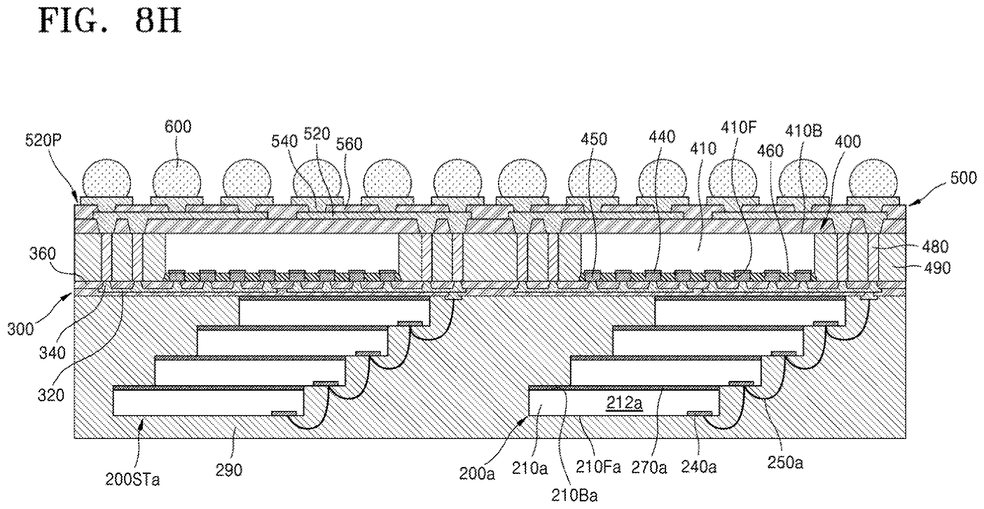

FIGS. 8A to 8H are cross-sectional views illustrating a method of manufacturing a semiconductor package, according to embodiments, and FIGS. 8A to 8H are views illustrating a method of manufacturing the semiconductor package 3 shown in FIG. 7, in which the same reference numerals as those of FIG. 7 denote substantially the same members, and the same description as those of the previous drawings may be omitted.

Referring to FIG. 8A, the connection redistribution layer 300 is formed on the support substrate 10 to which a release film 20 is attached. The connection redistribution layer 300 may include the connection redistribution line patterns 320, the connection redistribution vias 340, and the connection redistribution insulating layer 360.

Referring to FIG. 8B, at least one chip stack 200STa disposed on the connection redistribution layer 300 is formed. The at least one chip stack 200STa includes a plurality of sub-semiconductor chips 200a that are stacked, and the sub-semiconductor chips 200a included in the at least one chip stack 200STa may be shifted in a horizontal direction and stacked to have a step shape in a vertical direction. Each of the sub-semiconductor chips 200a may be sequentially stacked on the connection redistribution layer 300 after the sub-die adhesive film 270a is attached to the fourth non-active surface 210Ba, which is the lower surface.

The fourth chip connection members 250a may be formed to electrically connect the fourth front chip pads 240a included in the sub-semiconductor chips 200a to the connection redistribution line pattern 320.

Referring to FIG. 8C, the first molding layer 290 surrounding the chip stack 200STa and the fourth chip connection members 250a on the connection redistribution layer 300 is formed. The first molding layer 290 may surround the chip stack 200STa and the fourth chip connection members 250a and may be formed to cover the upper surface of the uppermost sub-semiconductor chip 200a among the sub-semiconductor chips 200a.

Referring to FIGS. 8C and 8D together, after removing the support substrate 10 to which the release film 20 is attached from the connection redistribution layer 300, a resultant structure is turned over so that the first molding layer 290 faces down and the connection redistribution layer 300 faces up.

Referring to FIG. 8E, the main semiconductor chip 400 is attached on the connection redistribution layer 300, and the connection posts 480 are formed. After the second chip connection members 450 is attached to the third front chip pads 440, the main semiconductor chip 400 may be attached to the upper surface of the connection redistribution layer 300 such that the third active surface 410F faces the connection redistribution layer 300. The main semiconductor chip 400 may be attached to the upper surface of the connection redistribution layer such that the second chip connection members 450 are connected to some of the connection redistribution line patterns 320 disposed on the upper surface of the connection redistribution layer 300. The underfill layer 460 surrounding the second chip connection members 450 is formed between the main semiconductor chip 400 and the connection redistribution layer 300.

The connection posts 480 may be formed on some of the other of the connection redistribution line patterns 320 disposed on the upper surface of the connection redistribution layer 300 so as to be apart from the main semiconductor chip 400 in a horizontal direction.

Referring to FIG. 8F, the second molding layer 490 surrounding the third semiconductor chip 400 and the connection posts 480 is formed on the connection redistribution layer 300. The second molding layer 490 may be formed to cover the upper surface of the third semiconductor chip 400, that is, the third non-active surface 410B and the upper surface of the connection posts 480.

Referring to FIGS. 8F and 8G together, the upper portion of the second molding layer 490 is removed to expose the third non-active surface 410B and the connection posts 480 of the third semiconductor chip 400.

Referring to FIG. 8H, the base redistribution layer 500 is formed on the second molding layer 490, and the package connection members 600 are attached to the external connection pads 520P.

Thereafter, the base redistribution layer 500, the second molding layer 490, the connection redistribution layer 300, and the first molding layer 290 may be cut to form a plurality of semiconductor packages 3 shown in FIG. 7.

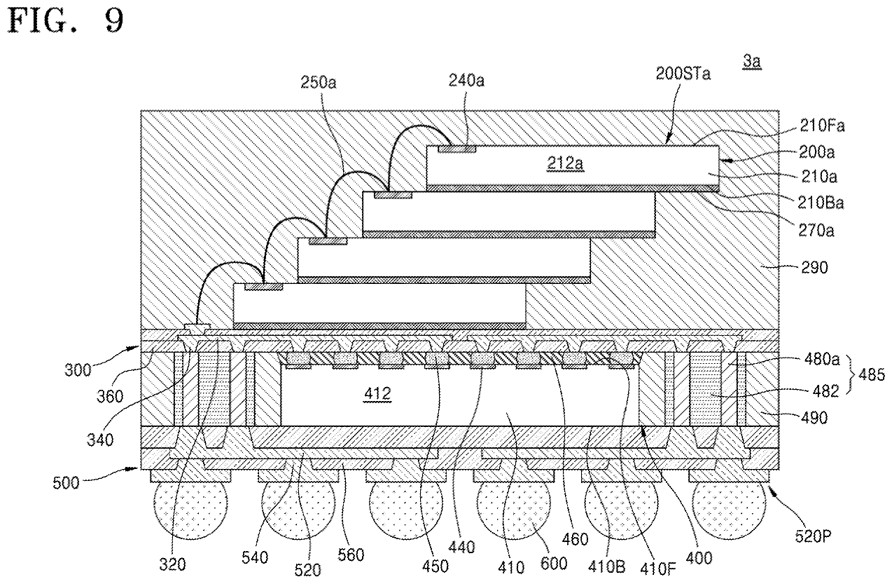

FIG. 9 is a cross-sectional view of a semiconductor package 3a according to example embodiments. In FIG. 9, the same reference numerals as those of FIGS. 7 and 3 denote substantially the same members, and the same description as those of FIGS. 7 and 3 may be omitted.

Referring to FIG. 9, the semiconductor package 3a includes the main semiconductor chip 400 disposed on the base redistribution layer 500, the connection redistribution layer 300 disposed on the main semiconductor chip 400, at least one chip stack 200STa disposed on the connection redistribution layer 300, the first molding layer 290 surrounding the sub-semiconductor chips 200a on the connection redistribution layer 300, and the second molding layer 490 interposed between the connection redistribution layer 300 and the base redistribution layer 500 and surrounding the main semiconductor chip 400.

The semiconductor package 3a may include the connection bars 485 interposed between the connection redistribution layer 300 and the base redistribution layer 500 to electrically connect the connection redistribution layer 300 to the base redistribution layer 500. The connection bar 485 may include a plurality of connection posts 480a and a cover insulating layer 482 surrounding the connection posts 480a.

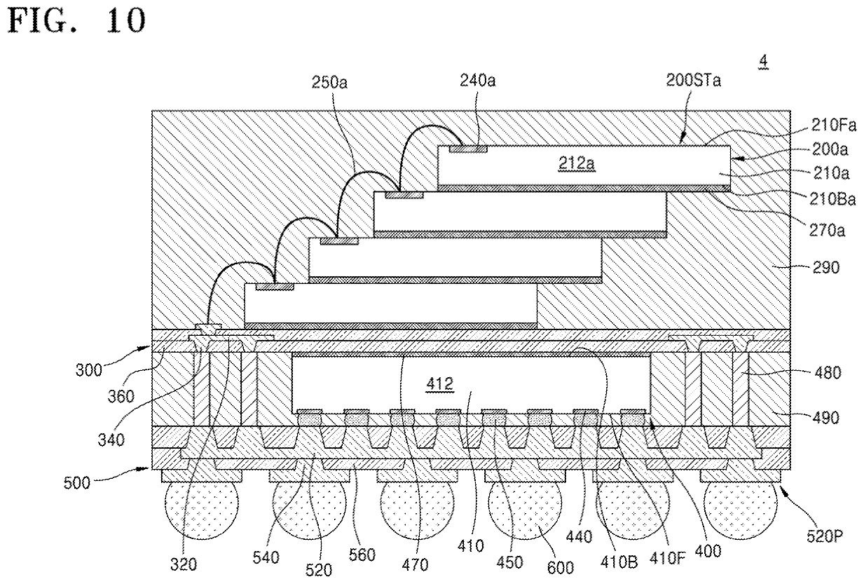

FIG. 10 is a cross-sectional view of a semiconductor package 4 according to example embodiments. In FIG. 10, the same reference numerals as those of FIGS. 7 and 4 denote substantially the same members, and the same description as those of FIGS. 7 and 4 may be omitted.

Referring to FIG. 10, the semiconductor package 4 may include the main semiconductor chip 400 disposed on a base redistribution layer 500, the connection redistribution layer 300 disposed on the main semiconductor chip 400, at least one chip stack 200STa disposed on the connection redistribution layer 300, the first molding layer 290 surrounding the sub-semiconductor chips 200a on the connection redistribution layer 300, the second molding layer 490 interposed between the connection redistribution layer 300 and the base redistribution layer 500 and surrounding the main semiconductor chip 400, and connection posts 480 passing through the second molding layer 490 and interposed between the connection redistribution layer 300 and the base redistribution layer 500. The main semiconductor chip 400 may be disposed such that the third active surface 410F faces the base redistribution layer 500.

The second chip connection members 450 may be disposed between the third front chip pads 440 and the base redistribution vias 540 or the base redistribution line patterns 520 disposed on the lower surface of the base redistribution layer 500 to electrically connect the main semiconductor chip 400 to the base redistribution layer 500. The second molding layer 490 may fill a space between the main semiconductor chip 400 and the base redistribution layer 500 and surround the second chip connection members 450.

The die adhesive film 470 may be attached to the third non-active surface 410B of the main semiconductor chip 400. In some embodiments, the die adhesive film 470 may fill a space between the third non-active surface 410B of the main semiconductor chip 400 and the lower surface of the connection redistribution layer 300.

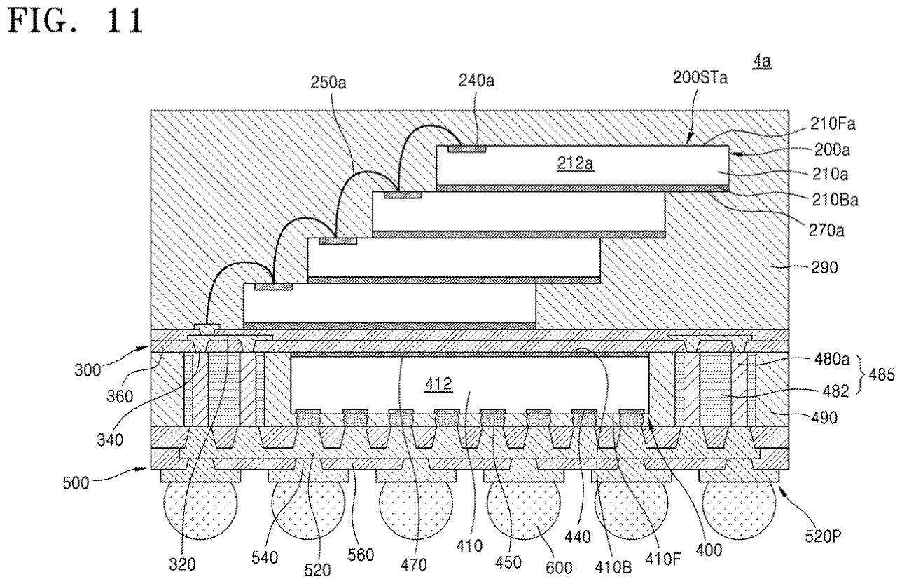

FIG. 11 is a cross-sectional view of a semiconductor package 4a according to example embodiments. In FIG. 11, the same reference numerals as those of FIGS. 10 and 3 denote substantially the same members, and the same description as those of FIGS. 10 and 3 may be omitted.

Referring to FIG. 11, the semiconductor package 4a may include the main semiconductor chip 400 disposed on the base redistribution layer 500, the connection redistribution layer 300 disposed on the main semiconductor chip 400, at least one chip stack 200STa disposed on the connection redistribution layer 300, the first molding layer 290 surrounding the sub-semiconductor chips 200a on the connection redistribution layer 300, and the second molding layer 490 interposed between the connection redistribution layer 300 and the base redistribution layer 500 to surround the main semiconductor chip 400. The main semiconductor chip 400 may be disposed such that the third active surface 410F faces the base redistribution layer 500.

The semiconductor package 4a may include the connection bars 485 interposed between the connection redistribution layer 300 and the base redistribution layer 500 to electrically connect the connection redistribution layer 300 to the base redistribution layer 500. The connection bar 485 may include the connection posts 480a and the cover insulating layer 482 surrounding the connection posts 480a.

While example embodiments have been particularly shown and described, it will be understood that various changes in form and details may be made therein without departing from the spirit and scope of the following claims.

What is claimed is:

1. A semiconductor package comprising:
a base redistribution layer;
a plurality of package connection members attached to a lower surface of the base redistribution layer;
a first semiconductor chip provided on the base redistribution layer;
at least two chip stacks stacked on the first semiconductor chip in a vertical direction, each chip stack of the at least two chip stacks comprising a plurality of second semiconductor chips electrically connected to the first semiconductor chip;
a first molding layer covering an upper surface of the first semiconductor chip and surrounding the at least two chip stacks;
a third semiconductor chip provided between the base redistribution layer and the first semiconductor chip and overlapping at least a portion of each of the at least two chip stacks in the vertical direction;
a plurality of connection posts provided between the base redistribution layer and the first semiconductor chip, the plurality of connection posts being configured to electrically connect the base redistribution layer to the first semiconductor chip and being spaced apart from the third semiconductor chip in a horizontal direction; and
a second molding layer surrounding the third semiconductor chip and the plurality of connection posts between the base redistribution layer and the first semiconductor chip.

2. The semiconductor package of claim 1, wherein an active surface of the first semiconductor chip faces active surfaces of the plurality of second semiconductor chips.

3. The semiconductor package of claim 1, wherein a horizontal width and a horizontal area of the first semiconductor chip are equal to a horizontal width and a horizontal area of each of the first molding layer, the second molding layer, and the base redistribution layer.

4. The semiconductor package of claim 1, further comprising:
a connection redistribution layer provided between the first semiconductor chip and the second molding layer,
wherein an active surface of the third semiconductor chip faces the connection redistribution layer.

5. The semiconductor package of claim 4, wherein a non-active surface of the third semiconductor chip contacts an upper surface of the base redistribution layer.

6. The semiconductor package of claim 4, wherein a non-active surface of the third semiconductor chip, lower surfaces of the plurality of connection posts, and a lower surface of the second molding layer are at a same vertical level to be coplanar with each other.

7. The semiconductor package of claim 1, wherein an active surface of the third semiconductor chip faces the base redistribution layer.

8. The semiconductor package of claim 6, wherein the third semiconductor chip comprises a die adhesive film attached to the non-active surface of the third semiconductor chip, and attached to a lower surface of the connection redistribution layer.

9. The semiconductor package of claim 7, wherein the third semiconductor chip is electrically connected to the base redistribution layer by a plurality of chip connection members between a lower surface of the third semiconductor chip and the base redistribution layer, and
wherein lower surfaces of the plurality of chip connection members, lower surfaces of the plurality of connection posts, and a lower surface of the second molding layer are positioned at a same vertical level to be coplanar with each other.

10. The semiconductor package of claim 1, wherein the first semiconductor chip and the plurality of second semiconductor chips constitute a high bandwidth memory (HBM), and
wherein the third semiconductor chip comprises a graphics processing unit (GPU) chip.

11. The semiconductor package of claim 5, wherein each chip stack of the at least two chip stacks comprises n second semiconductor chips)stacked in the vertical direction, and n is a multiple of 2, and
wherein a thickness of the third semiconductor chip is less than 1/n of a total thickness of the first semiconductor chip and the at least two chip stacks.

12. A semiconductor package comprising:
a base redistribution layer;
a plurality of package connection members attached to a lower surface of the base redistribution layer;
a connection redistribution layer provided on the base redistribution layer;
a main semiconductor chip comprising a graphics processing unit (GPU), and provided between the base redistribution layer and the connection redistribution layer;
a plurality of connection posts provided between the base redistribution layer and the connection redistribution layer to electrically connect the base redistribution layer to the connection redistribution layer, the plurality of connection posts being spaced apart from the main semiconductor chip in a horizontal direction;
at least one chip stack electrically connected to the connection redistribution layer, attached to the connection redistribution layer such that at least a portion of the at least one chip stack overlaps the main semiconductor chip in a vertical direction, the at least one chip stack comprising a plurality of sub-semiconductor chips;
a first molding layer covering an upper surface of the connection redistribution layer and surrounding at least some of the plurality of sub-semiconductor chips; and
a second molding layer configured to fill a space between the base redistribution layer and the connection redistribution layer and surrounding the plurality of connection posts.

13. The semiconductor package of claim 12, further comprising:
a first semiconductor chip provided between the connection redistribution layer and the first molding layer,
wherein the at least one chip stack comprises at least two chip stacks each chip stack comprising a plurality of the sub-semiconductor chips stacked on the first semiconductor chip in the vertical direction and spaced apart from each other in the horizontal direction, and
wherein the main semiconductor chip overlaps at least a portion of the at least two chip stacks in the vertical direction.

14. The semiconductor package of claim 13, wherein the plurality of sub-semiconductor chips are stacked on the first semiconductor chip such that a first active surface of the first semiconductor chip faces a second active surface of each of the plurality of sub-semiconductor chips.

15. The semiconductor package of claim 13, wherein a horizontal width and a horizontal area of the first semiconductor chip are equal to a horizontal width and a horizontal area of each of the first molding layer, the connection redistribution layer, the second molding layer, and the base redistribution layer.

16. The semiconductor package of claim 12, wherein a non-active surface of each sub-semiconductor chip of the plurality of sub-semiconductor chips faces the connection redistribution layer, and the plurality of sub-semiconductor chips are shifted in the horizontal direction to be stacked on the connection redistribution layer in the vertical direction and to have a step shape in the vertical direction.

17. The semiconductor package of claim 12, wherein corresponding side surfaces of the first molding layer, the connection redistribution layer, the second molding layer, and the base redistribution layer are aligned with each other in the vertical direction.

18. A semiconductor package comprising:
a base redistribution layer;
a plurality of package connection members attached to a lower surface of the base redistribution layer;
a connection redistribution layer provided on the base redistribution layer;
a first semiconductor chip attached on the connection redistribution layer and having comprising a first active surface;
at least two chip stacks, each chip stack of the at least two chip stacks comprising a plurality of second semiconductor chips having a second active surface facing the first active surface and stacked on the first semiconductor chip in a vertical direction, the at least two chip stacks being apart from each other in a horizontal direction;
a first molding layer configured to cover an upper surface of the first semiconductor chip and surrounding the at least two chip stacks;
a third semiconductor chip provided between the base redistribution layer and the connection redistribution layer and overlapping at least a portion of each of the at least two chip stacks in the vertical direction;
a plurality of connection posts provided apart from each other in the horizontal direction between the base redistribution layer and the connection redistribution layer, the plurality of connection posts being configured to electrically connect the base redistribution layer to the connection redistribution layer; and
a second molding layer surrounding the third semiconductor chip and the plurality of connection posts between the base redistribution layer and the connection redistribution layer, wherein corresponding side surfaces of the first molding layer, the first semiconductor chip, the connection redistribution layer, the second molding layer, and the base redistribution layer are aligned with each other in the vertical direction,
wherein the first semiconductor chip and the plurality of second semiconductor chips constitute a high bandwidth memory (HBM), and
wherein the third semiconductor chip comprises a graphics processing unit (GPU) chip.

19. The semiconductor package of claim 18, wherein a thickness of the third semiconductor chip is in a range from about 30 μm to about 80 μm.

20. The semiconductor package of claim 18, wherein a non-active surface of the third semiconductor chip, a lower surface of each of the plurality of connection posts, and a lower surface of the second molding layer are positioned at a same vertical level to be coplanar with each other and are in contact with an upper surface of the base redistribution layer.
